(19) United States
(12) Patent Application Publication
(10) Pub. No.: US 2009/0001397 A1
(43) Pub. Date: Jan. 1, 2009

(54) Method and device for providing circumferential illumination

(75) Inventors: Eran Fine, Tel-Aviv (IL); Noam Meir, Herzlia (IL)

Correspondence Address: Martin D. Moynihan;PRTSI, INC., P.O. Box 16446, Arlington, VA, 22215, US

(73) Assignee: Oree, Advanced Illumiation Solutions Inc., Ramat-Gan (IL)

(21) Appl. No.: 12/155,090

(22) Filed: May 29, 2008

Related U.S. Application Data
(60) Provisional application No. 60/924,716, filed on May 29, 2007.
(60) Provisional application No. 61/006,922, filed on Feb. 6, 2008.

(51) Int. Cl. H01L 33/00

(52) U.S. Cl. 257/98; 257/E33.061

(57) ABSTRACT

A light source device, comprising at least one light emitting element, an optical for distributing light emitted by the light emitting element(s) into a waveguide material which is in optical communication with the optical funnel, and at least one reflector contacting the waveguide material for redirecting light back into the waveguide material such as to reduce illumination exiting the waveguide material in any direction other than a circumferential direction.

### RELATED APPLICATIONS

This application claims the benefit of priority from U.S. Provisional Patent Applications Nos. 60/924,716 filed on May 29, 2007 and 61/006,922 filed on Feb. 6, 2008, the contents of which are hereby incorporated by reference as if fully set forth herein.

The contents of U.S. patent application Ser. No. 11/157,190 filed on Jun. 21, 2005, U.S. Provisional Patent Applications Nos. 60/580,705, filed on Jun. 21, 2004 and 60/687,865 filed on Jun. 7, 2005, and PCT Patent Application No. PCT/IL2006/000667 filed on Jun. 7, 2006 (Publication No. WO 2006/131924), are all hereby incorporated by reference as if fully set forth herein.

### FIELD AND BACKGROUND OF THE INVENTION

The present invention relates to artificial illumination and, more particularly, to a method and device for providing circumferential illumination.

Artificial light can be generated in many ways, including via electroluminescent illumination (e.g., light emitting diodes), incandescent illumination (e.g., conventional incandescent lamps, thermal light sources) and gas discharge illumination (e.g., fluorescent lamps, xenon lamps, hollow cathode lamps). Light can also be emitted via direct chemical radiation discharge of a photoluminescent (e.g., chemoluminescence, fluorescence, phosphorescence).

A light emitting diode (LED) is essentially a p-n junction semiconductor diode that emits a monochromatic light when operated in a forward biased direction. In the diode, current flows easily from the aside to the n-side but not in the reverse direction. When two complementary charge-carriers (an electron and a “hole”) collide, the electron-hole system experiences a transition to a lower energy level and emits a photon. The wavelength of the light emitted depends on the difference between the two energy levels, which in turn depends on the band gap energy of the materials forming the p-n junction.

LEDs are used in various applications, including traffic signal lamps, large-sized full-color outdoor displays, various lamps for automobiles, solid-state lighting devices, flat panel displays and the like. The basic structure of a LED consists of the light emitting semiconductor material, also known as the bare die, and numerous additional components deigned for improving the performance of the LED. These components include a light reflecting cup mounted below the bare die, a transparent encapsulation, typically epoxy, surrounding and protecting the bare die and the light reflecting cup, bonders, for supplying the electrical current to the bare die and an optical element for collimating the light. The bare die and the additional components are efficiently packed in a LED package.

Nowadays, the LED has won remarkable attention as a next-generation small-sized light emitting source. The LED has heretofore had advantages such as a small size, high resistance and long life, but has mainly been used as indicator illumination for various measuring meters or a confirmation lamp in a control state because of restrictions on a light emitting efficiency and light emitting output. However, in recent years, the light emitting efficiency has rapidly been improved, and it is said to be a matter of time that the light emitting efficiency exceeds that of a high-pressure mercury lamp or a fluorescent lamp of a discharge type which has heretofore been assumed to have a high efficiency. Due to the appearance of the high-efficiency high-luminance LED, a high-output light emitting source using the LED has rapidly assumed a practicability.

The application of the high-efficiency high-luminance LED has been considered as a promising small-sized light emitting source of an illuminating unit which is requested to have a light condensing capability. The LED originally has characteristics superior to those of another light emitting source, such as life, durability, lighting speed, and lighting driving circuit. Furthermore, above all, blue is added, and three primary colors are all used in a self-light emitting source, and this has enlarged an application range of a full-color image displays.

Luminescence is a phenomenon in which energy is absorbed by a substance, commonly called a luminescent, and emitted in the form of light. The absorbed energy can be in a form of light (photons), electrical field or colliding particles (e.g., electrons). The wavelength of the emitted light differs from the characteristic wavelength of the absorbed energy (the characteristic wavelength equals hclE, where h is the Plank's constant, c is the speed of light and E is the energy absorbed by the luminescent).

The luminescence is a widely occurring phenomenon which can be classified according to the excitation mechanism as well as according to the emission mechanism. Examples of such classifications include photoluminescence, electroluminescence, fluorescence and phosphorescence. Similarly, luminescent materials are classified into photoluminescents materials, electroluminescent materials, fluorescent materials and phosphorescent materials, respectively.

A photoluminescent is a material which absorbs energy is in the form of light, an electroluminescent is a material which absorbs energy is in the form of electrical field, a fluorescent material is a material which emits light upon return to the base state from a singlet excitation, and a phosphorescent materials is a material which emits light upon return to the base state from a triplet excitation.

In fluorescent materials, or fluorophores, the electron de-excitation occurs almost spontaneously, and the emission ceases when the source which provides the exciting energy to the fluorophore is removed.

In phosphor materials, or phosphors, the excitation state involves a change of spin state which decays only slowly. In phosphorescence, light emitted by an atom or molecule persists after the exciting source is removed.

Luminescent materials are selected according to their absorption and emission characteristics and are widely used in cathode ray tubes, fluorescent lamps, X-ray screens, neutron detectors, particle scintillators, ultraviolet (UV) lamps, flat panel displays and the like.

Luminescent materials, particularly phosphors, are also used for altering the color of LEDs. Since blue light has a short wavelength (compared, e.g., to green or red light), and since the light emitted by the phosphor has a longer wavelength than the absorbed light, blue light generated by a blue LED can be readily converted to produce visible light having a longer wavelength. For example, a blue LED coated by a suitable yellow phosphor can emit white light. The phosphor absorbs the light from the blue LED and emits in a broad spectrum, with a peak in the yellow region. The photons emitted by the phosphor and the non-absorbed photons emitted of the LED are perceived together by the human eye as white light. The first commercially available phosphor based white led was produced by Nichia Co. The white LED consisted of a gallium indium nitride (InGaN) blue LED coated by a yellow phosphor.

In order to get sufficient brightness, a high intensity LED is needed to excite the phosphor to emit the desired color. As commonly known white light is composed of various colors of the whole range of visible electromagnetic spectrum. In the case of LEDs, only the appropriate mixture of complementary monochromatic colors can cast white light. This is achieved by having at least two complementary light sources in the proper power ratio. A “fuller” light (similar to sunlight) can be achieved by adding more colors. Phosphors are usually made of zinc sulfide or yttrium oxides doped with certain transition metals (Ag, Mn, Zn, etc.) or rare earth metals (Ce, Eu, Tb, etc.) to obtain the desired colors.

In a similar mechanism, white LEDs can also be manufactured using fluorescent semiconductor material instead of a phosphor. The fluorescent semiconductor material serves as a secondary emitting layer, which absorbs the light created by the light emitting semiconductor and reemits yellow light. The fluorescent semiconductor material, typically an aluminum gallium indium phosphide (AlGaInP), is bonded to the primary source wafer.

Another type of light emitting device is an organic light emitting diode (OLED) which makes use of thin organic films. An OLED device typically includes an anode layer, a cathode layer, and an organic light emitting layer containing an organic compound that provides luminescence when an electric field is applied. OLED devices are generally (but not always) intended to emit light through at least one of the electrodes, and may include one or more transparent electrodes.

Traditional LEDs emit light over a wide solid angle. Such illumination profile is useful when the LED is used as an indicator, because it allows viewing the LED from many directions. Yet, wide solid angle illumination renders inefficient any attempt to couple the emitted light into an optical device such as an optical waveguide. Thus, LED based optical transmission systems inevitably include an arrangement of lenses or diffractive elements for improving the coupling efficiency between the LED and the optical relay device.

U.S. Pat. No. 7,293,908 discloses a side-emitting illumination system that incorporates a LED. A portion of the light internally generated by a LED is recycled back to the light emitting diode as externally incident light. The LED reflects the recycled light and redirects it through the output aperture of the side-emitting illumination system.

### SUMMARY OF THE INVENTION

According to an aspect of some embodiments of the present invention there is provided a light source device, comprising: at least one light emitting element; an optical funnel being constituted for distributing light emitted by the at least one light emitting element into a waveguide material which is in optical communication with the optical funnel; and at least one reflector contacting the waveguide material for redirecting light back into the waveguide material such as to reduce illumination exiting the waveguide material in any direction other than a circumferential direction.

According to an aspect of some embodiments of the present invention there is provided a light source device, comprising: at least one light emitting element; a waveguide material for distributing light emitted by the at least one light emitting element; and at least one reflector contacting the waveguide material for redirecting light back into the waveguide material such as to reduce illumination exiting the waveguide material in any direction other than a circumferential direction; wherein a surface area of the reflector is at least two times, more preferably at least five times, more preferably at least ten times the surface area of the light emitting element and the optical efficiency of the light source device is at least 60%.

According to an aspect of some embodiments of the present invention there is provided there is provided illumination apparatus which comprises at least one light source device as described herein, and a light distribution device being configured for distributing illumination provided by the at least one light source device.

According to some embodiments of the invention the light distribution device of the apparatus is an integral extension of the at least one light source device.

According to an aspect of some embodiments of the present invention there is provided there is provided illumination apparatus. The apparatus comprises: at least one light emitting element; a waveguide material for distributing light emitted by the at least one light emitting element; and at least one reflector contacting at least one surface of the waveguide material for redirecting light back into the waveguide material; the waveguide material extending beyond the at least one reflector and being configured for distributing illumination through an extended portion of the at least one surface.

According to an aspect of some embodiments of the present invention there is provided a method of generating light. The method comprises applying forward bias to the light source device or apparatus described herein.

According to some embodiments of the present invention the waveguide is incorporated with particles capable of scattering said light.

According to some embodiments of the present invention optical funnel is incorporated with particles capable of scattering said light.

According to some embodiments of the present invention a size of said plurality of particles is selected so as to selectively scatter a predetermined spectrum of said light.

According to some embodiments of the present invention the optical funnel is an optical resonator being designed and constructed such that circumferential illumination provided by the device is substantially white.

According to some embodiments of the present invention the optical funnel is an optical resonator being designed and constructed such that circumferential illumination provided by the device has a substantially uniform brightness.

According to some embodiments of the present invention the optical funnel is adjacent to the waveguide material and being external thereto.

According to some embodiments of the present invention the optical funnel is embedded in the waveguide material.

According to some embodiments of the invention the optical funnel protrudes out of a surface of the waveguide material.

According to some embodiments of the invention the optical funnel is flash with an external surface of the waveguide material the waveguide material.

According to some embodiments of the present invention the light emitting elements are embedded in the optical funnel.

According to some embodiments of the present invention the reflector(s) comprises a specular mirror.

According to some embodiments of the present invention the reflector(s) comprises a Lambertian reflector.

According to some embodiments of the present invention the reflector(s) reflector comprises a diffusive reflector.

According to some embodiments of the present invention, an illumination profile provided by the device is characterized in that at least 80% illumination is distributed within a colatitude range of from about 45° to about 135°.

According to some embodiments of the present invention the reflector(s) comprises a non-planar reflector.

According to some embodiments of the present invention the reflector(s) comprises a curved part and a generally planar part being peripheral to the curved part, the curved part being positioned opposite to a location of the at least one light emitting element.

According to some embodiments of the present invention the light emitting element is a light emitting diode.

According to some embodiments of the present invention the light emitting diode is embedded within the waveguide.

According to some embodiments of the present invention the light emitting diode is a bare die.

According to some embodiments of the present invention the waveguide material is flexible.

According to some embodiments of the present invention the waveguide material comprises at least one photoluminescent layer.

According to some embodiments of the present invention the optical funnel comprises at least one photoluminescent layer.

According to some embodiments of the present invention the photoluminescent layer(s) and the light emitting element(s) are selected to provide a substantially white light.

According to some embodiments of the present invention the photoluminescent layer(s) is embedded in the waveguide material and/or the optical funnel.

According to some embodiments of the present invention the photoluminescent layer(s) is disposed on a surface of the waveguide material and/or the optical funnel.

According to some embodiments of the present invention the photoluminescent layer(s) is disposed on an end of the waveguide material and/or the optical funnel.

According to some embodiments of the present invention there is a plurality of photoluminescent layers each being characterized by a different absorption spectrum, and a plurality of light emitting elements, such that for each absorption spectrum there is a light emitting element characterized by an emission spectrum overlapping the absorption spectrum.

According to some embodiments of the present invention the waveguide material comprises a plurality of photoluminescent particles embedded therein.

According to some embodiments of the present invention the optical funnel comprises a plurality of photoluminescent particles embedded therein.

According to some embodiments of the present invention the device further comprises at least one optical element for deflecting the light upon entry to the optical funnel.

According to some embodiments of the present invention the optical element(s) comprises a refractive optical element.

According to some embodiments of the present invention the optical element(s) comprises a diffractive optical element.

According to some embodiments of the present invention the reflector(s) comprises a planar reflector.

According to some embodiments of the present invention the light emitting element comprises a bare die and electrical contacts connected thereto.

According to some embodiments of the present invention the light emitting element is encapsulated by a transparent thermal isolating encapsulation.

According to some embodiments of the present invention the waveguide material has a first surface and a second surface and the light emitting element is embedded near the second surface.

According to some embodiments of the present invention the light emitting element is embedded near the second surface of the waveguide material.

According to some embodiments of the present invention the light emitting element is embedded near the second surface in a manner such that electrical contacts of the light emitting source remain outside the waveguide material at the second surface.

According to some embodiments of the present invention the device or apparatus further comprising a printed circuit board electrically connected to the electrical contacts.

According to some embodiments of the present invention the printed circuit board is capable of evacuating heat away from the light emitting element.

According to some embodiments of the present invention the device or apparatus further comprises a heat sink element configured for evacuating heat away from the light emitting element.

According to some embodiments of the present invention the waveguide material comprises a polymeric material.

According to some embodiments of the present invention the waveguide material comprises a rubbery material.

According to some embodiments of the present invention the waveguide material is formed by dip-molding in a dipping medium.

According to some embodiments of the present invention the dipping medium comprises a hydrocarbon solvent in which a rubbery material is dissolved or dispersed.

According to some embodiments of the present invention the dipping medium comprises additives selected from the group consisting of cure accelerators, sensitizers, activators, emulsifying agents, cross-linking agents, plasticizers, antioxidants and reinforcing agents

According to some embodiments of the present invention the waveguide material comprises a dielectric material, and wherein a reflection coefficient of the dielectric material is selected so as to allow propagation of polarized light through the waveguide material and emission of the polarized light through a surface of the waveguide material.

According to some embodiments of the present invention the waveguide material comprises a metallic material, and wherein a reflection coefficient of the metallic material is selected so as to allow propagation of polarized light through the waveguide material and emission of the polarized light through a surface of the waveguide material.

According to some embodiments of the present invention the waveguide material is a multilayered material.

According to some embodiments of the present invention the waveguide material comprises a first layer having a first refractive index, and a second layer being in contact with the first layer and having a second refractive index being larger that the first refractive index.

According to some embodiments of the present invention the second layer comprises polyisoprene.

According to some embodiments of the present invention the first layer comprises silicone.

According to some embodiments of the present invention the waveguide material further comprises a third layer being in contact with the second layer and having a third refractive index being smaller than the second refractive index.

According to some embodiments of the present invention the third refractive index equals the first refractive index.

According to some embodiments of the present invention layer of waveguide material comprises additional component designed and configured such as to allow emission of the light through a surface of the waveguide material.

According to some embodiments of the present invention the additional component is capable of producing different optical responses to different spectra of the light.

According to some embodiments of the present invention the different optical responses comprise different emission angles.

According to some embodiments of the present invention the different optical responses comprise different emission spectra.

According to some embodiments of the present invention the additional component comprises impurity capable of emitting at least the portion of the light through the first surface.

According to some embodiments of the present invention the impurity comprises a plurality of particles capable of scattering the light.

According to some embodiments of the present invention a size of the plurality of particles is selected so as to selectively scatter a predetermined spectrum of the light.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. In case of conflict, the patent specification, including definitions, will control. In addition, the materials, methods, and examples are illustrative only and not intended to be limiting.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1a schematically illustrate an exploded view of a light source device, according to various exemplary embodiments of the present invention;

FIG. 1b shows a representative illumination profile of the device according to a preferred embodiment of the present invention;

FIG. 1c is a schematic illustration of light propagation in a waveguide material according to various exemplary embodiments of the present invention;

FIG. 1d is a schematic illustration of an embodiment in which a reflector of the device has a curved part;

FIGS. 2a-c are fragmentary schematic illustrations showing a cross-section of an optical funnel according to various exemplary embodiments of the present invention;

FIGS. 2d-e schematic illustrations depicting relations between an optical funnel and a waveguide material, according to various exemplary embodiments of the present invention;

FIGS. 3a-d are fragmentary schematic illustrations showing a cross-section of the waveguide material according to various exemplary embodiments of the present invention;

FIGS. 3e-g are fragmentary schematic illustrations showing a cross-section of the waveguide material and the optical funnel according to various exemplary embodiments of the present invention;

FIGS. 4a-b are schematic fragmentary views of the device in a preferred embodiment in which a light emitting element is embedded in the bulk of the waveguide material (FIG. 4a), and in another preferred embodiment in which the light emitting element is embedded near the surface of the waveguide material (FIG. 4b);

FIGS. 5a-d are schematic illustrations of an illumination apparatus according to various exemplary embodiments of the present invention;

FIG. 5e schematically illustrates a perspective view of the apparatus in a preferred embodiment in which a light distribution device of the apparatus is non-planar;

FIG. 6a is a schematic illustration of the waveguide material in a preferred embodiment in which two layers are employed;

FIGS. 6b-c are schematic illustrations of the waveguide material in preferred embodiments in which three layers are employed;

FIG. 7a is a schematic illustration of the waveguide material in a preferred embodiment in which at least one impurity is used for scattering light;

FIG. 7b is a schematic illustration of the waveguide material in a preferred embodiment in which the impurity comprises a plurality of particles having a gradually increasing concentration;

FIG. 7c is a schematic illustration of the waveguide material in a preferred embodiment in which one layer thereof is formed with one or more diffractive optical elements for at least partially diffracting the light;

FIG. 7d is a schematic illustration of the waveguide material in a preferred embodiment in which one or more regions have different indices of refraction so as to prevent the light from being reflected.

FIG. 8 is a fragmentary view of a simulation setup in accordance with preferred embodiments of the present invention;

FIG. 9a shows distribution of light emitted by the light source device as a function of the colatitude and longitude, as obtained from computer simulations performed according to various exemplary embodiments of the present invention;

FIG. 9b shows light distribution within the waveguide material as obtained from computer simulations performed according to various exemplary embodiments of the present invention;

FIG. 9c shows the intensity of light emitted by the light source device as a function of φ, for θ=95°, as obtained from simulations performed according to various exemplary embodiments of the present invention;

FIG. 10 shows measured intensity as a function of the wavelength for a light source device having a surface-emitting flexible waveguide material and a LED with a narrow direct emission spectrum centered at a wavelength of 460 nm, and a broad stokes shifted spectrum centered at about 560 nm;

FIG. 11 shows results of an experiment in which the intensity of light emitted from the light source device of the present embodiments was measured for various vertical and horizontal angles;

FIGS. 12a-b demonstrate the ability of the device of the present embodiments to allow color mixing;

FIGS. 13a-b demonstrate the color mixing uniformity of the device of the present embodiments;

FIG. 14 shows a comparison between the optical outputs of the light source device of the present embodiments for different types of waveguide materials;

FIG. 15 shows relative optical efficiency of materials as a function of the mean free path;

FIG. 16 is a histogram comparing the relative efficiency of the light source device of the present embodiments for various types of waveguides materials;

FIGS. 17a-b are schematic illustrations of a cross-sectional view (FIG. 17a) and a perspective view (FIG. 17b) of a light source device used in computer simulations, performed according to various exemplary embodiments of the present invention;

FIGS. 18a-b are graphs showing optical efficiency of the device illustrated in FIGS. 17a-b as a function of radii of a front reflector and a rear reflector as obtained in computer simulations performed according to various exemplary embodiments of the present invention; and

FIG. 19 is a graph showing the optical efficiency as a function of the radii of the front reflector and the rear reflector, in embodiments of the present invention in which the waveguide is incorporated with particles.

### DESCRIPTION OF THE PREFERRED EMBODIMENTS

The present invention is of a device apparatus and method which can be used for generating light. Specifically, the present invention can be used to provide substantially circumferential illumination.

The principles and operation of a device apparatus and method according to the present invention may be better understood with reference to the drawings and accompanying descriptions.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

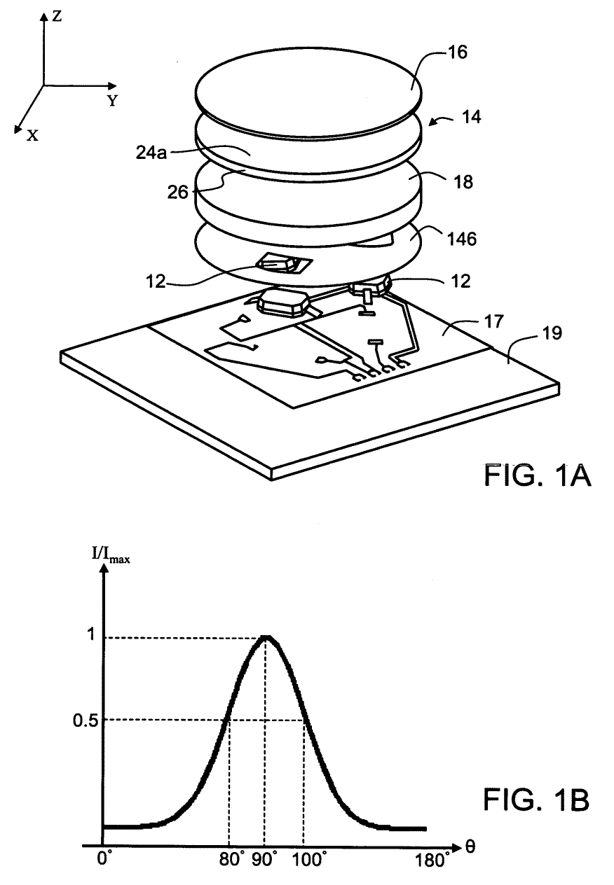

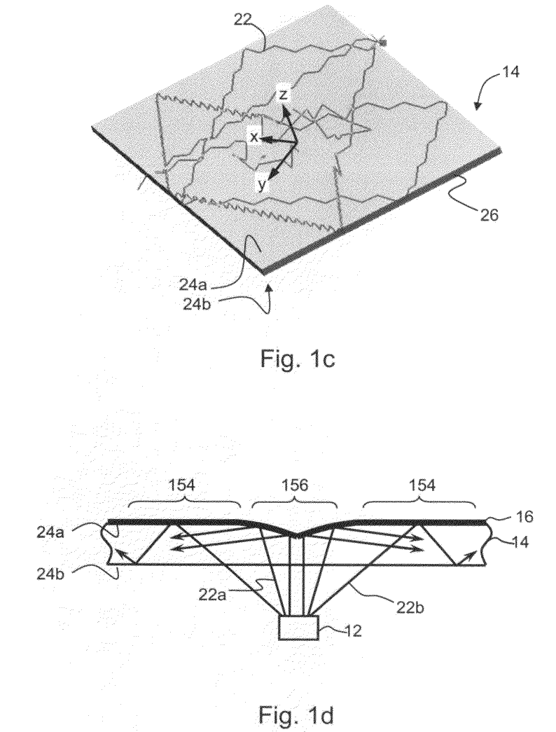

Referring now to the drawings, FIG. 1a schematically illustrates an exploded view of a light source device 10, according to various exemplary embodiments of the present invention. Device 10 comprises one or more light emitting elements 12, one or more reflectors 16, and a waveguide material 14 having surfaces 24a and 24b and one or more ends 26. In various exemplary embodiments of the invention device 10 further comprises a printed circuit board 17 which supplies the forward bias to the light emitting element(s). In this embodiment, board 17 can be made, at least in part, or it can be attached to a heat conducting material 19 so as to facilitate evacuation of heat away from element 12.

Waveguide material 14 serves for distributing light emitted by element(s) 12. Waveguide material 14 generally has two surfaces 24a and 24b (see FIG. 1c) and one or more ends 26. Light emitted from elements 12 enters waveguide material 14 through surface 24b and exits waveguide material 14 through at least a portion of end 26. In various exemplary embodiments of the invention the amount of light exiting device 10 through surface 24a of waveguide material 14 is substantially suppressed. In some embodiment, the amount of optical energy exiting device 10 through surface 24a of waveguide material 14 is less than 10%, more preferably less than 5%, more preferably less than 2%, more preferably less than 1%, of the amount of optical energy entering waveguide material 14 through surface 24b. Surface 24b is also referred to herein as “bottom surface 24b” or “rear surface 24b” and surface 24a is also referred to herein as “top surface 24a” or “front surface 24a”. Since light enters waveguide material 14 through surface 24b, surface 24b is also referred to as “light entry surface 24b”.

Reflector(s) 16 serve for reducing illumination in any direction other than a circumferential direction. Below, directions are defined in term of polar angles θ, also known as colatitudes, and azimuthal angles φ, also known as longitudes. The range of possible colatitudes is from 0° to 180°, and the range of possible longitudes is from 0° to 360°. Colatitude of 0° is referred to as the vertical direction and colatitude of 180° is referred to as opposite to the vertical direction. All directions having colatitude of 90° are referred to as circumferential directions.

Also shown in FIG. 1a is a Cartesian coordinate system, oriented such that the vertical direction is along the z axis and all circumferential directions are in the x-y plane.

One of the advantages of device 10 is that it has a substantially circumferential illumination profile. As further detailed hereinunder and demonstrated in the Examples section that follows, such illumination profile significantly reduces optical losses in particular when device 10 is optically coupled to an additional optical device.

In various exemplary embodiments of the invention at least 80% of the illumination provided by device 10 is distributed within a colatitude range of from about 45° to about 135°, more preferably from about 70° to about 110°, more preferably about 80° to about 100°.

As used herein the term “about” refers to ±10%.

A representative illumination profile of device 10 according to a preferred embodiment of the present invention is illustrated in FIG. 1b. Shown in FIG. 1b is the dependence of the emitted light intensity on the colatitude. As shown, the maximal light intensity Iₘₐₓ is emitted at 90° while the light intensity at any colatitude θ below 80° or above 100° is half the maximal intensity or less.

The illumination profile of device 10 can be controlled by judicious selection of reflector(s) 16 and/or waveguide material 14. In various exemplary embodiments of the invention device 10 comprises a front reflector 16 and a rear reflector 146 positioned at or near front surface 24a and rear surface 24b of waveguide material 14, respectively. Generally, reflector 16 prevents emission of light through surface 24a and reflector 146 prevents emission of light through surface 24b of waveguide material 14, such that any light ray which impinges on reflectors 16 and 146 is redirected back into waveguide material 14 and continues to propagate therein. According to a preferred embodiment of the present invention the reflectivity of the reflectors and the transmittance of waveguide material are selected such as to minimize absorbance of light. In various exemplary embodiments of the invention at least 80%, more preferably at least 85%, e.g., 90% or more of the light emitted by element 22 exit device 10.

The reflector(s) and/or the waveguide material are preferably selected to provide substantially uniform brightness at a predetermined range of azimuthal angles. For example, the brightness can be substantially uniform across the range 0°≦φ≦360°. Alternatively, the brightness can be substantially uniform across a reduced range. This embodiment is particularly useful when it is desired to provide directional illumination or to prevent a certain range of azimuthal angles from receiving illumination. For example, device 10 can be designed to provide substantially uniform brightness across the range 0°≦φ≦120°, and no or suppressed illumination at other azimuthal angles.

Brightness uniformity can be calculated by considering the luminance deviation across the range of azimuthal angles as a fraction of the average luminance across that range. A more simple definition of the brightness uniformity (BU), is BU=1−(L_{MAX}−L_{MIN})/(L_{MAX}+L_{MIN}), where L_{MAX} and L_{MIN} are, respectively, the maximal and minimal luminance values across the predetermined range of azimuthal angles.

The term substantially uniform brightness refers to a BU value which is at least 0.8 when calculated according to the above formula. In some embodiments of the invention the value of BU is at least 0.85, more preferably at least 0.9, more preferably at least 0.95.

The light propagation in waveguide material 14 according to various exemplary embodiments of the present invention is better illustrated in FIG. 1c. Shown in FIG. 1c are waveguide material 14, generally oriented parallel to the x-y plane, and several light rays 22 propagating therein. Light rays 22 experience multiple scatterings and reflections within waveguide material 14. Additionally, light rays 22 attempting to exit waveguide material 14 through its upper or lower surfaces 24 are redirected by reflector 16 (not shown) back into waveguide material 14. Rays 22 continue to propagate within waveguide material 14 until they reach end 26 through which they exit. Preferably, waveguide material 14 is designed and manufactured such that the distribution of light within waveguide material 14 is substantially uniform. Simulations and experiments of light distribution are provided in the Example section that follows.

The reflector(s) of device 10 can be flat or it can have a curvature, as desired. When two or more reflectors are employed, one or more of the reflectors can have a curvature while other reflectors can be flat. FIG. 1d is a schematic illustration of an embodiment in which front reflector 16 has a curvature. FIG. 1d shows a portion of waveguide material 14, and reflector 16 engaging front surface 24a of waveguide material 14. In this illustrative Example, bottom surface 24b is not engaged with a reflector, but this need not necessarily be the case, since, for some applications, it may be desired to engage at least part of surface 24b by a reflector which may be flat or curved. In some embodiments of the present invention reflector 16 is curved into waveguide material 14 such as to disperse light rays impinging thereon. In the embodiment illustrated in FIG. 1d, reflector 16 has a curved part 156 and a generally planar part 154, arranged such that curved part 156 is generally opposite to the location of light emitting element 12, and planar part 154 is peripheral to curved part 156. Light rays 22a entering waveguide material 14 at sufficiently small angles impinge on curved part 156 and are disperse thereby to a sufficiently large angle. Light rays 22b entering waveguide material 14 at sufficiently large angles impinge on planar part 154 and are reflected thereby to substantially maintain their large angles.

This configuration further facilitates the substantially uniform distribution of light within waveguide material 14.

It is to be understood that FIG. 1d is a fragmentary view of the waveguide material and the reflector. Thus reflector may include more than one curved part and more than one planar part, is desired. For example, when there are three light emitting elements, the reflector may include three curved parts each located generally opposite to one light emitting element. In some embodiments of the present invention two or more light emitting elements are located opposite to the same curved part of the reflector.

Reflector(s) 16 can be of any type known in the art. In some embodiments of the present invention a specular reflector is employed. A specular reflector generally has the property that the angle of light incidence equals the angle of reflection, where the incident and reflection angles are measured relative to the direction normal to the surface of the reflector. In these embodiments, the reflector(s) can be mirror-like reflector(s) with a smooth surface, either planar or non-planar as further detailed hereinabove.

In some embodiments of the present invention one or more of reflector(s) 16 has a Lambertian surface. A Lambertian surface is a surface which obeys Lambert's cosine law according to which the reflected or transmitted luminous intensity in any direction from an element of a perfectly diffusing surface varies as the cosine of the angle between that direction and the normal vector of the surface. When a photon hits a Lambertian surface, it rebounds in a statistically independent direction which is not much related to the incoming direction of the photon. Thus, a Lambertian surface is a surface whose radiance is substantially independent of direction. A surface which nearly obeys (say, within 80% accuracy, more preferably 90% accuracy or more) Lambert's cosine law is referred to herein as a “near-Lambertian surface”. A reflector having a Lambertian surface or a near-Lambertian surface is referred to herein as a “Larnbertian reflector”.

Also contemplated are diffusive reflectors which are similar to Lambertian reflectors but which do not exactly obey Lambert's cosine law. For example, a diffusive reflector can have a surface which are partially smooth and partially non-smooth.

The surface area of reflector(s) 16 is typically, but not obligatorily, larger than the overall surface area of light emitting elements 12 by a factor of at least 2, more preferably at least 5, more preferably at least 10. For example, when three light emitting elements are employed, each having a surface area of about 1 mm², the surface area of reflector(s) 16 is preferably at least 6 mm², more preferably at least 15 mm², more preferably at least 30 mm². As demonstrated in the Examples section that follows, large surface area of reflector(s) 16 significantly improves the efficiency of optical device 10 in the sense that more than 50%, or more than 55% or more than 60% or more that 65% of the optical power generated by light emitting elements 12 is provided as circumferential illumination through end 26 of waveguide material 14.

In an article entitled “LED-Based Light-Recycling Light Sources for Projection Displays,” written by Beeson et al. and published in 2006 in the Journal SID international symposium digest of technical papers volume 37 book 2, pages 1823-1826, the authors teach that in order to achieve high efficiency and brightness from an optical cavity it is necessary to introduce into the cavity a LED having a partially reflective top electrode, such that when light is recycled back onto the LED it is redirected by the top electrode into the optical cavity. Specifically, Beeson et al. teach that for efficiency of above 60% it is necessary to provide the LED with a top electrode having a reflectivity of at least 70%, whereas a non-reflective top electrode results in efficiency of only 30%.

It was found by the inventors of the present invention that large surface area of reflector(s) 16 reduces the need of light recycling back onto the light emitting elements. For example, it was found by the inventors of the present invention that even with a fully transparent LED, device 10 can provide circumferential illumination at efficiency of 69.7%, which is almost the same efficiency that would have been obtained with a LED having a 50% reflective top electrode. Thus, in various exemplary embodiments of the invention light emitting elements 12 are made substantially light transmissive, e.g., having reflectivity of less than 30%, more preferably less than 20%, more preferably less than 10%, more preferably less than 2%.

Waveguide material 14 is preferably a light scattering material which is characterized by an enhanced scattering coefficient. This improves the ability of material 14 to allow distribution of light therein and, consequently, the ability of device 10 to provide substantially circumferential illumination.

It is generally known that light transport through a scattering medium is effected by the values of the absorption coefficient, λ_{A}, and the scattering coefficient, λ_{S}. The absorption coefficient refers to the probability of light absorption per unit path length, and the scattering coefficient refers to the probability of light scattering per unit path length. In various exemplary embodiments of the invention the scattering coefficient of waveguide material 14 is significantly larger than the absorption coefficient thereof. Specifically, according to the presently preferred embodiment of the invention λ_{S}=R×λ_{A}, where R is a number greater than 1, more preferably greater than the ratio of scattering coefficient to absorption coefficient of PMMA.

For sufficiently transparent materials with low absorption coefficient, the scattering properties can also be expressed in terms of the mean free path of a light ray within the material. The mean free path can be measured directly by positioning a bulk material in front of light emitting element and measuring the optical output through the bulk at a given direction as a function of the thickness of the bulk. Typically, when a bulk material, t mm in thickness, reduces the optical output of the light source at the forward direction by 50% the material is said to have a mean free path of t mm.

In various exemplary embodiments of the invention waveguide material 14 is characterized by an optical mean free path which is from about 0.3 mm to about 150 mm, more preferably from about 1 mm to about 100 mm. Representative examples of material suitable for the present embodiments include, without limitation, Exact 0203 (Trademark of ExxonMobil Corporation), Eng 8500 (Trademark of Dow), Styrolux 693D (trademark of BASF), and Surlyn 1601 (trademark of DuPont).

Light emitting element 12 of device 10 can be element which is capable of self emission of light rays, including, without limitation, an inorganic light emitting diode, an organic light emitting diode or any other electroluminescent element.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

Organic light emitting diodes suitable for the present embodiments can be bottom emitting OLEDs, top emitting OLEDs and side emitting OLEDs, having one or two transparent electrodes.

Light emitting element 12 can be a LED, which includes the bare die and all the additional components packed in the LED package, or, more preferably, light emitting element 12 can include the bare die, excluding one or more of the other components (e.g., reflecting cup, silicon, LED package and the like).

As used herein “bare die” refers to a p-n junction of a semiconductor material. When a forward biased is applied to the p-n junction through electrical contacts connected to the p side and the n side of the p-n junction, the p-n junction emits light at a characteristic spectrum.

Thus, in various exemplary embodiments of the invention light emitting element 12 includes only the semiconductor p-n junction and the electrical contacts. Also contemplated are configurations in which several light sources are LEDs, and several light sources other are bare dies with electrical contacts connected thereto.

The advantage of using a bare die rather than a LED is that some of the components in the LED package including the LED package absorb part of the light emitted from the p-n junction and therefore reduce the light yield.

Another advantage is that the use of bare die reduces the amount of heat generated during light emission. This is because heat is generated due to absorption of light by the LED package and reflecting cup. The consequent increase in temperature of the p-n junction causes thermal imbalance which is known to reduce the light yield. Since the bare die does not include the LED package and reflecting cup, the embedding of a bare die in the waveguide material reduces the overall amount of heat and increases the light yield. The elimination of the LED package permits the use of many small bare dies instead of each large packaged LED. Such configuration allows operating each bare die in low power while still producing sufficient overall amount of light, thereby to improving the p-n junction efficacy.

An additional advantage is light diffusion within the waveguide material. The minimization of redundant components in the vicinity of the p-n junction results in almost isotropic emission of light from the p-n junction which improves the diffusion of light. To further improve the coupling efficiency, the waveguide material is preferably selected with a refraction index which is close to the refraction index of the p-n junction.

Light emitting elements 12 can be embodied in any form known in the art and they can provide monochromatic or chromatic light, depending on the type of illumination for which device 10 is designed. The characteristic emission spectrum of the light emitting element is also referred to herein as “the color” of the light emitting element. Thus, for example, a light emitting element characterized by a spectrum having an apex at a wavelength of from about 420 to about 500 nm, is referred to as a “blue light emitting element”, a light emitting element characterized by a spectrum having an apex at a wavelength of from about 520 to about 580 nm, is referred to as a “green light emitting element”, a light emitting element characterized by a spectrum having an apex at a wavelength of about 620-680 nm, is referred to as a “red light emitting element”, and so on for other colors. This terminology is well-known to those skilled in the art of optics.

Several light emitting elements can be employed such as to provide white illumination or illumination at any other color mixing. When light rays having multiple wavelengths emitted by elements 12, the optical properties of waveguide material 14 and/or reflector 16 are selected such that there is a substantially uniform color mixing in waveguide material 14. The color uniformity is typically expressed in terms of maximal color deviations for a specific color coordinate of the CIE 1931 color space. In various exemplary embodiments of the invention the color deviation within waveguide material 14 is less than 0.02, more preferably less than 0.015, e.g., 0.01 or less for any color coordinate X, Y or Z of the CIE 1931 color space.

Specific output profile (specifically, but not exclusively, color uniformity or uniform white light) of device 10 can also be provided using the luminescence phenomenon described above. This embodiment can be implemented in more than one way. Typically, but not exclusively, specific output profile can be provided using one or more photoluminescent layers, which can be disposed on or embedded in waveguide material 14.

The term “photoluminescent layer” is commonly used herein to describe one photoluminescent layer or a plurality of photoluminescent layers. Additionally, a photoluminescent layer can comprise one or more types of photoluminescent molecules. In any event, a photoluminescent layer is characterized by an absorption spectrum (i.e., a range of wavelengths of light which can be absorbed by the photoluminescent molecules to effect quantum transition to a higher energy level) and an emission spectrum (i.e., a range of wavelengths of light which are emitted by the photoluminescent molecules as a result of quantum transition to a lower energy level). The emission spectrum of the photoluminescent layer is typically wider and shifted relative to its absorption spectrum. The difference in wavelength between the apex of the absorption and emission spectra of the photoluminescent layer is referred to as the Stokes shift of the photoluminescent layer.

The absorption spectrum of the photoluminescent layer preferably overlaps the emission spectrum of at least one of light emitting elements 12. More preferably, for each characteristic emission spectrum of a light emitting element, there is at least one photoluminescent layer having an absorption spectrum overlapping the emission spectrum the light emitting element. According to a preferred embodiment of the present invention the apex of the element's emission spectrum lies in the spectrum of the photoluminescent layer, and/or the apex of the photoluminescent layer's absorption spectrum lies in the spectrum of the element.

The photoluminescent layer serves for “converting” the wavelength of a portion of the light emitted by light emitting elements 12. More specifically, for each photon which is successfully absorbed by the layer, a new photon is emitted. Depending on the type of photoluminescent, the emitted photon can have a wavelength which is longer or shorter than the wavelength of the absorbed photon. Photons which do not interact with the photoluminescent layer propagate therethrough. The combination of converted light and non-converted light forms the output profile of device 10.

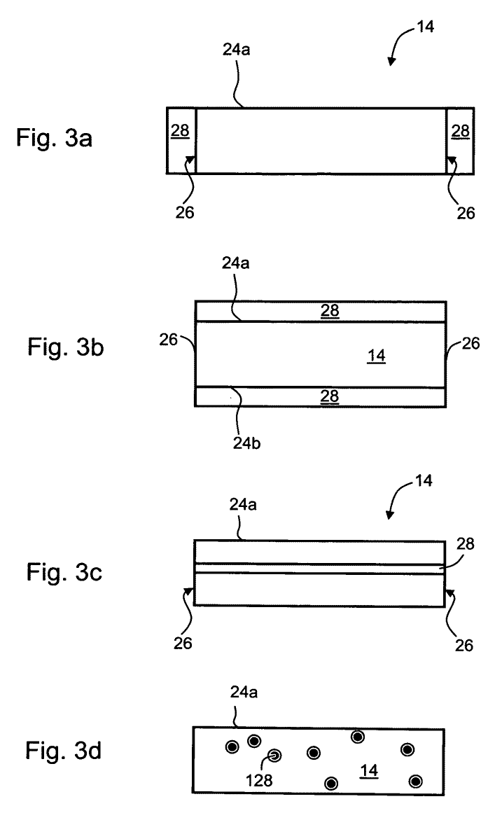

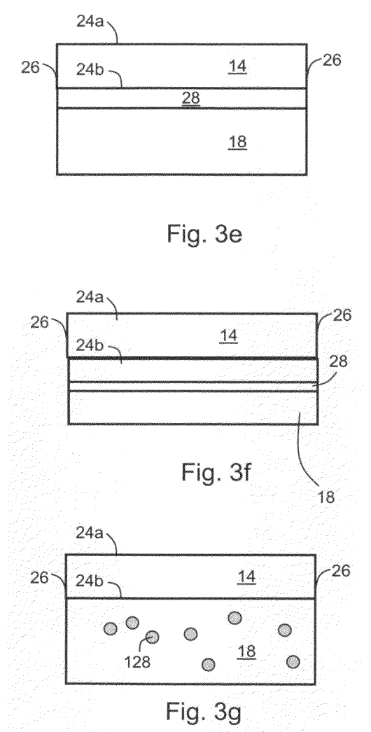

FIG. 3a is a fragmentary schematic illustration of device 10 showing a cross-section of waveguide material 14 parallel to the Z-Y plane. FIG. 3a illustrates an embodiment in which ends 26 of waveguide material 14 are coated by one or more photoluminescent layers 28. Photoluminescent layer 28 comprises a photoluminescent material which can be a phosphor or a fluorophore.

FIG. 3b is a schematic illustration of an embodiment in which photoluminescent layer 28 is disposed on one or more of the surfaces 24 of waveguide material 14. In this embodiment, the wavelength of the light is changed via the multiple impingements of the light on surfaces 24. Also contemplated, is a configuration in which only one of the surfaces is coated by the photoluminescent layer. For example, the upper surface can be coated by the photoluminescent layer and the lower surface can be left exposed for better light coupling between waveguide material 14 and light emitting elements 12. If desired, the upper surface can be exposed and the lower surface can be coated by the photoluminescent layer.

FIG. 3c is a schematic illustration of an embodiment in which photoluminescent layer 28 is embedded within waveguide material 14.

In any of the above embodiments the area of layer 28 can either fully or partially overlap the area of waveguide material 14.

Photoluminescent material can also be incorporated in the form of particles. This embodiment is illustrated in FIG. 3d. A plurality of photoluminescent 128 is distributed within waveguide material 14 in accordance with the desired output profile. For example, in one embodiment, the particles are uniformly distributed in the waveguide. In another embodiment, the particles are distributed such that there are regions with higher population of the particles and region with lower population of the particles, depending on the desired profile near each region. In an additional embodiment, the particles are distributed so as to form a layer within the waveguide material (see, for example, layer 28 in FIG. 3c). Combination between a photoluminescent layer and a distribution of embedded photoluminescent particles is also contemplated.

Phosphors are widely used for coating individual LEDs, typically in the white LEDs industry. However, photoluminescent layers covering the end of a waveguide material such as the waveguide material of the present embodiments have not been employed. The advantage of providing layer 28 and/or particles 128 as opposed to on each individual light emitting element 12, is that waveguide material 14 diffuses the light before emitting it. Thus, instead of collecting light from a point light source (e.g., a LED), layer 28 and/or particles 128 collects light from a light source having a predetermined area. This configuration allows a better control on the light profile provided by device 10.

Many types of phosphorescent and fluorescent substance are contemplated. Representative examples include, without limitation the phosphors disclosed in U.S. Pat. Nos. 5,813,752, 5,813,753, 5,847,507, 5,959,316, 6,155,699, 6,351,069, 6,501,100, 6,501,102, 6,522,065, 6,614,179, 6,621,211, 6,635,363, 6,635,987, 6,680,004, 6,765,237, 6,853,131, 6,890,234, 6,917,057, 6,939,481, 6,982,522, 7,015,510, 7,026,756 and 7,045,826 and 7,005,086.

There is more than one configuration in which layer 28 can be used. In one embodiment, layer 28 serves for complementing the light emitted by light emitting elements 12 to a white light, e.g., using dichromatic, trichromatic, tetrachromatic or multichromatic approach.

For example, a blue-yellow dichromatic approach can be employed, in which case blue light emitting elements (e.g., bare dies of InGaN with a peak emission wavelength at about 460 nm), can be distributed in waveguide material 14, and layer 28 can be made of phosphor molecules with absorption spectrum in the blue range and emission spectrum extending to the yellow range (e.g., cerium activated yttrium aluminum garnet, or strontium silicate europium). Since the scattering angle of light sharply depends on the frequency of the light (fourth power dependence for Rayleigh scattering, or second power dependence for Mie scattering), the blue light generated by the blue light emitting elements is efficiently diffused in the waveguide material before interacting with layer 28 and/or particles 128. Layer 28 and/or particles 128 emit light in its emission spectrum and complement the blue light which is not absorbed by layer 28 and/or particles 128 to white light.

In another dichromatic configurations, ultraviolet light emitting elements (e.g., bare dies of GaN, AlGaN and/or InGaN with a peak emission wavelength between 360 nm and 420 nm), can be distributed in waveguide material 14. Light of such ultraviolet light emitting elements is efficiently diffused in the waveguide material. To provide substantially white light, two photoluminescent layers and/or two types of photoluminescent particles are preferably employed. One such layer and/or type of particles can be characterized by an absorption spectrum in the ultraviolet range and emission spectrum in the orange range (with peak emission wavelength from about 570 nm to about 620 nm), and another layer and/or type of particles can be characterized by an absorption spectrum in the ultraviolet range and emission spectrum in the blue-green range (with peak emission wavelength from about 480 nm to about 500 nm). The orange light and blue-green light emitted by the two photoluminescent layers and/or two types of photoluminescent particles blend to appear as white light to a human observer. Since the light emitted by the ultraviolet light emitting elements is above or close to the end of visual range it is not seen by the human observer. When two photoluminescent layers are employed, they can be deposited one on top of the other such as to improve the uniformity. Alternatively, a single layer having two types of photoluminescent with the above emission spectra can be deposited.

In another embodiment a trichromatic approach is employed. For example, blue light emitting elements can be distributed in the waveguide material as described above, with two photoluminescent layers and/or two types of photoluminescent particles. A first photoluminescent layer and/or type of photoluminescent particles can be made of phosphor molecules with absorption spectrum in the blue range and emission spectrum extending to the yellow range as described above, and a second photoluminescent layer and/or type of photoluminescent particles can be made with absorption spectrum in the blue range and emission spectrum extending to the red range (e.g., cerium activated yttrium aluminum garnet doped with a trivalent ion of praseodymium, or europium activated strontium sulphide). The unabsorbed blue light, the yellow light and the red light blend to appear as white light to a human observer.

Also contemplated is a configuration is which light emitting elements with different emission spectra are distributed and several photoluminescent layers are deposited and/or several types of photoluminescent particles are distributed, such that the absorption spectrum of each photoluminescent layer and/or type of photoluminescent particles overlaps one of the emission spectra of the light emitting elements, and all the emitted colors (of the light emitting elements and the photoluminescent layers and/or particles) blend to appear as white light. The advantage of such multi-chromatic configuration is that it provides high quality white balance because it allows better control on the various spectral components of the light in a local manner along the circumference of the device.

The color composite of the white output light depends on the intensities and spectral distributions of the emanating light emissions. These depend on the spectral characteristics and spatial distribution of the light emitting elements, and, in the embodiments in which one or more photoluminescent objects (layers and/or particles) are employed, on the spectral characteristics of the photoluminescent objects and the amount of unabsorbed light. The amount of light that is unabsorbed by the photoluminescent objects is in turn a function of the characteristics of the objects, e.g., thickness of the photoluminescent layer(s), density of photoluminescent material(s) and the like. By judiciously selecting the emission spectra of light emitting element 12 and optionally the thickness, density, and spectral characteristics (absorption and emission spectra) of layer 28 and/or particle 128, device 10 can be made to provide substantially uniform white light.

In any of the above embodiments, the “whiteness” of the light can be tailored according to the specific application for which device 10 is used. For example, when device 10 is incorporated for backlight of an LCD device, the spectral components of the light provided by device 10 can be selected in accordance with the spectral characteristics of the color filters of the liquid crystal panel. In other words, since a typical liquid crystal panel comprises an arrangement of color filters operating at a is plurality of distinct colors, the white light provided by device 10 includes at least at the distinct colors of the filters. This configuration significantly improves the optical efficiency as well is the image quality provided by the LCD device, because the optical losses due to mismatch between the spectral components of the backlight unit and the color filters of the liquid crystal panel are reduced or eliminated.

Thus, in the embodiment in which the white light is achieved by light emitting elements emitting different colors of light (e.g., red light, green light and blue light), the emission spectra of the light emitting elements are preferably selected to substantially overlap the characteristic spectra of the color filters of the LCD panel. In the embodiment in which device 10 is supplemented by one or more photoluminescent objects (layers and/or particles) the emission spectra of the photoluminescent objects and optionally the emission spectrum or spectra of the light emitting elements are preferably selected to overlap the characteristic spectra of the color filters of the LCD panel. Typically the overlap between a characteristic emission spectrum and a characteristic filter spectrum is about 70% spectral overlap, more preferably about 80% spectral overlap, even more preferably about 90%.

Light emitting elements 12 can be embedded in waveguide material 14 or they can be external thereto. Additionally, light can enter waveguide material 14 either directly or via an optical funnel 18. In embodiments in which elements 12 are external to waveguide material 14, light preferably enters waveguide material 14 through surface 24. In embodiments in which optical funnel 18 is employed, light generated by elements 12 is collected by funnel 18 and distributed thereby into waveguide material 14. Elements 12 can be embedded within optical funnel 18 or they can be external thereto. Efficient optical transmission between funnel 18 and waveguide material 14 can be ensured by impedance matching and/or using an arrangement of optical elements as further detailed hereinbelow.

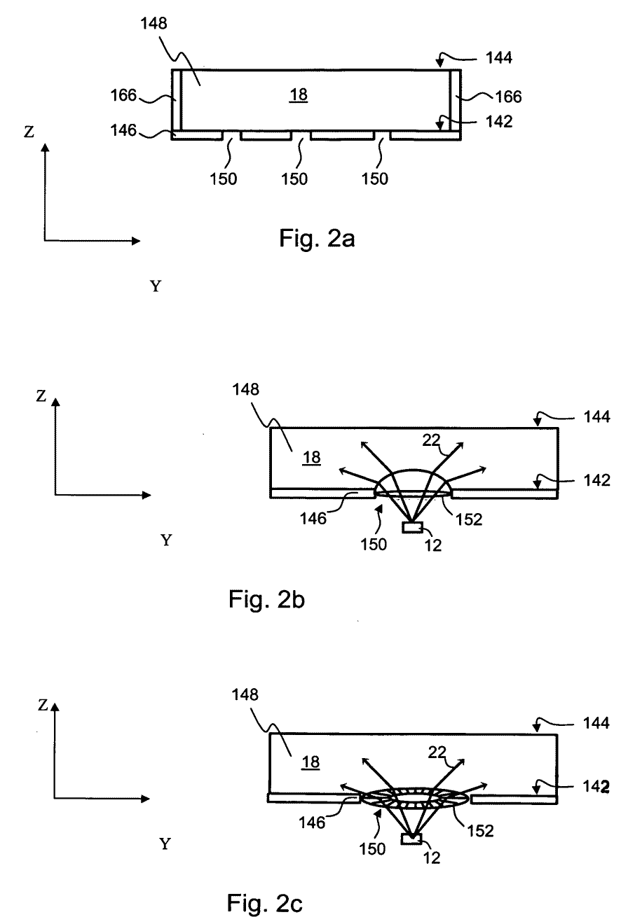

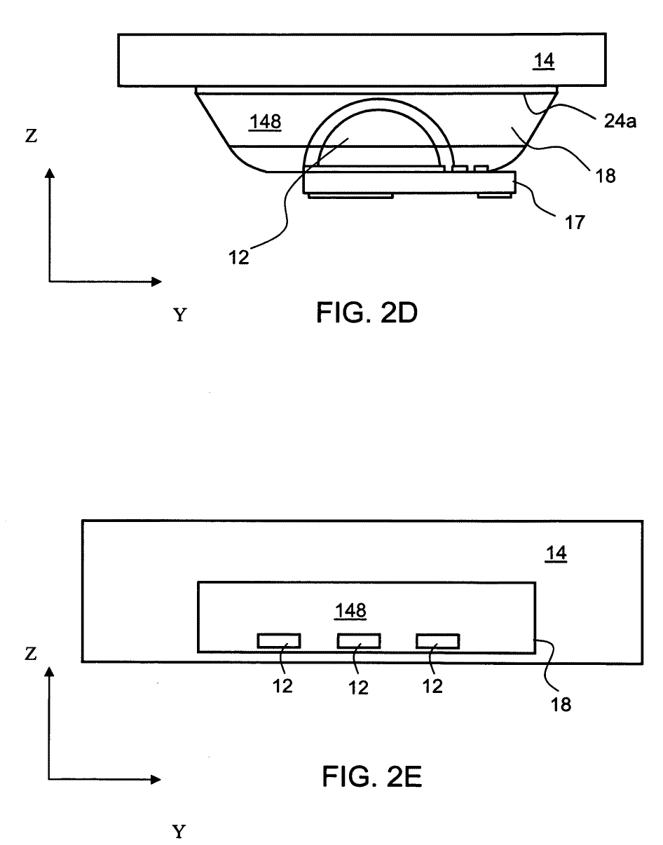

A cross sectional view of optical funnel 18 is illustrated in FIGS. 2a-c. Optical funnel 18 serves for distributing the emitted light prior to the entry into waveguide material 14 (not shown in FIGS. 2a-c, see FIG. 1a) so as to establish a plurality of entry locations into waveguide material 14 hence to further improve the uniformity of light distribution within waveguide material 14. Funnel 18 can be made as a surface-emitting waveguide and/or surface-emitting optical cavity which receives the light generated by light emitting elements 12 (not shown in FIGS. 2a-c, see FIG. 1a), distributes it within the internal volume 148 of funnel 18 and emits it through an exit surface 144, which is typically opposite to the first surface. When light emitting elements 12 are embedded within funnel 18, light is already generated within volume 148. When light emitting elements 12 are external to funnel 18, light enters volume 148 through an entry surface 142 of funnel 18.

In some embodiments of the present invention funnel 18 comprises one or more peripheral light reflectors 166, which are typically arranged peripherally about volume 148 such as to form an optical cavity or an optical resonator within volume 148. Additionally or alternatively rear light reflectors 146 can be formed on or attached to the entry surface 142 of funnel 18. When light emitting elements 12 are external to funnel 18, one or more openings 150 can be are formed on rear reflectors 146 for allowing the light to enter volume 148. Openings 150 can be located at the same horizontal (X-Y) location as emitting elements 12. Any of the reflectors which engage funnel 18, particularly (but not exclusively) rear reflector 146, can be flat or it can have a curvature as described hereinabove with respect to front reflector 16 (see FIG. 1d).

Funnel 18 can be made of a waveguide material or it can be filled with a medium with small absorption coefficient to the spectra or spectrum emitted by the light emitting elements. For example, funnel can be filled with air, or be made of a waveguide material which is similar or identical to waveguide material 14. The advantage of using air is the low absorption coefficient, and the advantageous of a waveguide material which is identical to waveguide material 14 is impedance matching.

When funnel 18 is filled with medium with small absorption coefficient (e.g., air) there is no impedance matching at exit surface 144 of funnel 18. Thus, some reflections and refraction events can occur upon the impingement of light on the interface between funnel 18 and waveguide material 14. Both refraction and reflection events do not cause significant optical losses, because refraction events contribute to the distribution of light within waveguide material 14, and reflection events contribute to the distribution of light within volume 148.

In some embodiments of the present invention funnel 18 comprises at least one optical element 152 for deflecting light entering the funnel. These embodiments are exemplified in the fragmentary views of FIGS. 2b-c. Elements 152 are preferably designed and constructed to deflect the light to enter funnel 18 at an angle which allows the propagation of light within waveguide material 14. In embodiments in which funnel is made of a waveguide material, elements 152 are preferably designed and constructed to deflect the light to enter funnel 18 at an angle which allows a few (i.e., at least two) internal reflections of the light within funnel 18. Typically, elements 152 deflect the light such that it enters funnel 18 at a non-zero angle with respect to the normal to the entry surface 142 thereof.

Each of elements 152 can be a refractive element or a diffractive element.

FIG. 2b is a fragmentary view of funnel 18 in the embodiment in which a refractive element is employed. Shown in FIG. 2b is one opening 150 formed in light reflector 146 at entry surface 142 of funnel 18. Element 152 engages opening 150 such that light 22 from light emitting element 12 passes through element 152 and is refracted thereby before entering volume 148 of funnel 18. In this embodiment, elements 152 can comprise a lens, e.g., a concave dome-shaped lens, or a plurality of mini- or micro-prisms, and the redirection of light is generally by the refraction phenomenon described by Snell's law. Element 152 can also be in the form of a transparent encapsulation covering light emitting element 12. Refractive elements in the form of a lens are known in the art and are found, e.g., in U.S. Pat. Nos. 7,006,306, 6,554,462 and 6,226,440, the contents of which are hereby incorporated by reference. Refractive elements in the form of mini- or micro-prisms are known in the art and are found, e.g., in U.S. Pat. Nos. 5,969,869, 6,941,069 and 6,687,010, the contents of which are hereby incorporated by reference.

FIG. 2c is a fragmentary view of funnel 18 in the embodiment in which a diffractive element is employed. Shown in FIG. 2c is one opening 150 formed in light reflector 146 at entry surface 142 of funnel 18. Element 152 engages opening 150 such that light 22 from light emitting element 12 passes through element 152 and is diffracted thereby before entering volume 148 of funnel 18. In this embodiment, elements 152 can comprise a diffraction grating such as a radial or a circular grating.

FIGS. 2d-e schematically illustrate the relations between funnel 18 and waveguide material 14 according to various exemplary embodiments of the present invention. For clarity of presentation, the reflectors are not shown in FIGS. 2d-e. Yet, it is to be understood that in any of the embodiments, device 10 may include one or more light reflectors as further detailed hereinabove. As illustrated in FIGS. 2d-e, optical funnel 18 can be positioned adjacent to waveguide material 14 (FIG. 2d), or it can be embedded within waveguide material 14 (FIG. 2e).

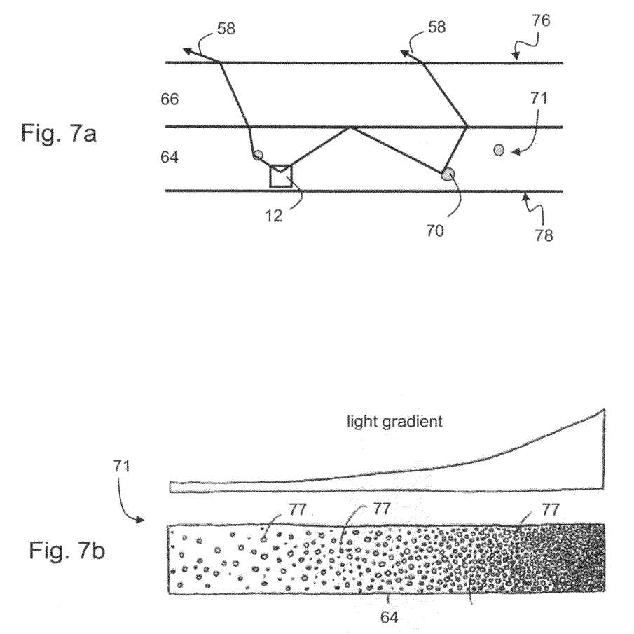

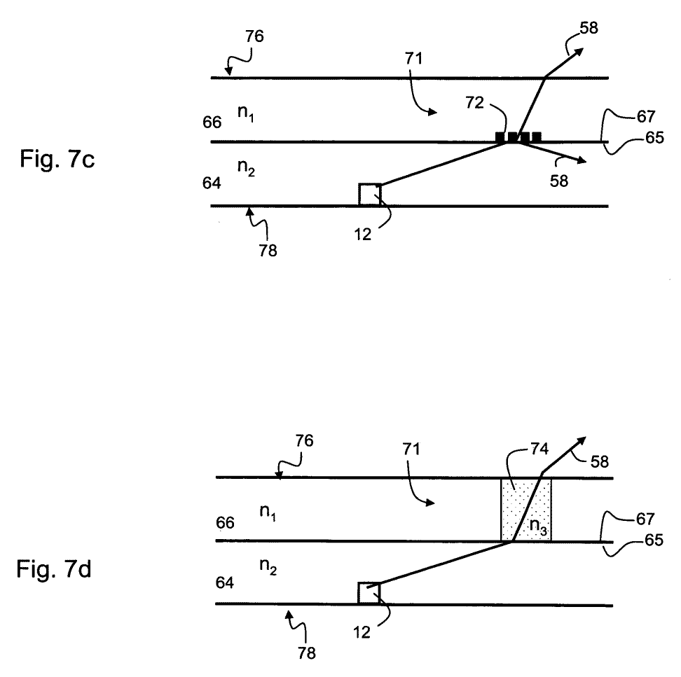

When funnel 18 external to waveguide material 14, light enters waveguide material 14 through surface 24a. Light can experience multiple reflection events at the boundaries of funnel 18 before refracting out into waveguide material 14. When funnel 18 is embedded within waveguide material 14, the refraction coefficient of funnel 18 (particularly volume 148) is typically, but not obligatorily, different from the refraction coefficient of waveguide material 14. In such an optical configuration, funnel 18 serves as an internal optical resonator wherein many photons generated by elements 12 may experience multiple internal reflection events at the boundaries between funnel 18 waveguide material 14 before refracting out into waveguide material 14. In any of the above embodiments, funnel 18 can be of a surface-emitting waveguide having therein impurities such as scatterers or the like (not shown, see FIGS. 7a-d hereinunder). In these embodiments, photons generated by elements 12 may experience multiple scattering events within volume 148 before refracting out into waveguide material 14.

In various exemplary embodiments of the invention funnel 18 is supplemented by photoluminescent material, for controlling the output profile of the light. FIGS. 3e-g schematically illustrate various embodiments for incorporating the photoluminescent material. For clarity of presentation, the reflectors are not shown in FIGS. 3e-g. Yet, it is to be understood that in any of the embodiments, device 10 may include one or more light reflectors as further detailed hereinabove.

In the embodiment illustrated in FIG. 3e, photoluminescent layer 28 is interposed between waveguide material 14 and funnel 18; in the embodiment illustrated in FIG. 3f, photoluminescent layer 28 is embedded in funnel 18; and in the embodiment illustrated in FIG. 3g a plurality of photoluminescent particles 128 is distributed within funnel 18. Photoluminescent layer 28 can also be formed or applied on the walls of funnel 18.

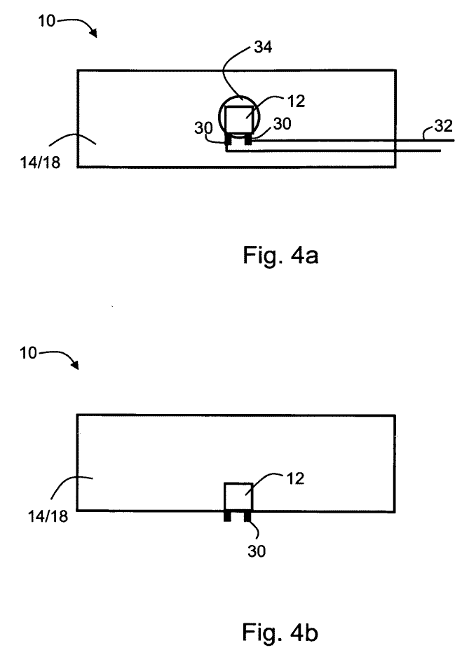

Element 12 can be embedded in the bulk of waveguide material 14 or funnel 18 or near its surface. FIG. 4a is a fragmentary view schematically illustrating the embodiment in which element 12 is embedded in the bulk of material 14 or funnel 18 and FIG. 4b is fragmentary view schematically illustrating the embodiment in which element 12 is embedded near the surface of material 14 or funnel 18. It is to be understood that FIGS. 4a-b illustrate a single light emitting element for clarity of presentation and it is not intended to limit the scope of the present invention to such configuration. As stated, device 10 can comprise one or more light emitting elements.

Referring to FIG. 4a, when element 12 is embedded in the bulk of the waveguide material or the funnel, the electrical contacts 30 remain with material 14. In this embodiment, the forward bias can be supplied to element 12 by electrical lines 32, such as flexible conductive wires, which are also embedded in material 14 or funnel 18. Thus, lines 32 extend from contacts 30 to one or more of the ends of the waveguide material or funnel. Element 12 including the electrical lines 32 can be embedded during the manufacturing process of material 14 or funnel 18. When a plurality of elements are embedded, they can be connected to an arrangement of electrical lines as known in the art and the entire of elements and arrangement of electrical lines can be embedded during the manufacturing process.

In various exemplary embodiments of the invention element 12 is operated with low power and therefore does not produce large amount of heat. This is due to the relatively large light yield of the embedded element and the high optical coupling efficiency between the element and the waveguide material or funnel. In particular, when element 12 is a bare die, its light yield is significantly high while the produced heat is relatively low. Element 12 can also be operated using pulsed electrical current which further reduces the amount of produced heat.

Preferably, but not obligatorily, element 12 is encapsulated by a transparent thermal isolating encapsulation 34. Encapsulation 34 serves for thermally isolating the element from the material in which it is embedded. This embodiment is particularly useful when element 12 is a bare die, in which case the bare die radiate heat which may change the optical properties of material 14 or funnel 18. Alternatively or additionally, waveguide material 14 or funnel 18 can be made with high specific heat capacity to reduce or eliminate undesired heating effects.

Referring to FIG. 4b, when element 12 is embedded near the surface of material 14 or funnel 18, electrical contacts 30 can remain at the surface outside the embedding material and can therefore be accessed without embedding the electrical lines. The electrical contacts can be applied with forward bias using external electrical lines or directly from printed circuit board 17 (not shown, see FIG. 1a). When the heat evacuation by board 17 is sufficient, element 12 can be embedded without thermal isolating encapsulation 34.

The waveguide material and/or the funnel according to embodiments of the present invention may be similar to, and/or be based on, the teachings of U.S. patent application Ser. Nos. 11/157,190, 60/580,705 and 60/687,865, all assigned to the common assignee of the present invention and fully incorporated herein by reference. Alternatively, the waveguide material according to some embodiments of the present invention may also have other configurations and/or other methods of operation as further detailed hereinunder.

The waveguide material and/or the funnel can be translucent or clear as desired. In any event, the waveguide material and/or funnel is transparent at least to the characteristic emission spectrum of element. The waveguide material and/or funnel is optionally and preferably flexible, and may also have a certain degree of elasticity. Thus, the waveguide material and/or funnel can be, for example, an elastomer. It is to be understood that although the waveguide material and funnel appear to be flat in FIGS. 1a, 1c, 2a-c and 3a-g, this need not necessarily be the case since for some applications it may not be necessary for the light source device to be flat.

Light source device 10 can be used as a light source in illumination apparatus. The advantageous of device 10 is that it provides substantially circumferential illumination profile which allows optical coupling with significantly reduced optical losses.

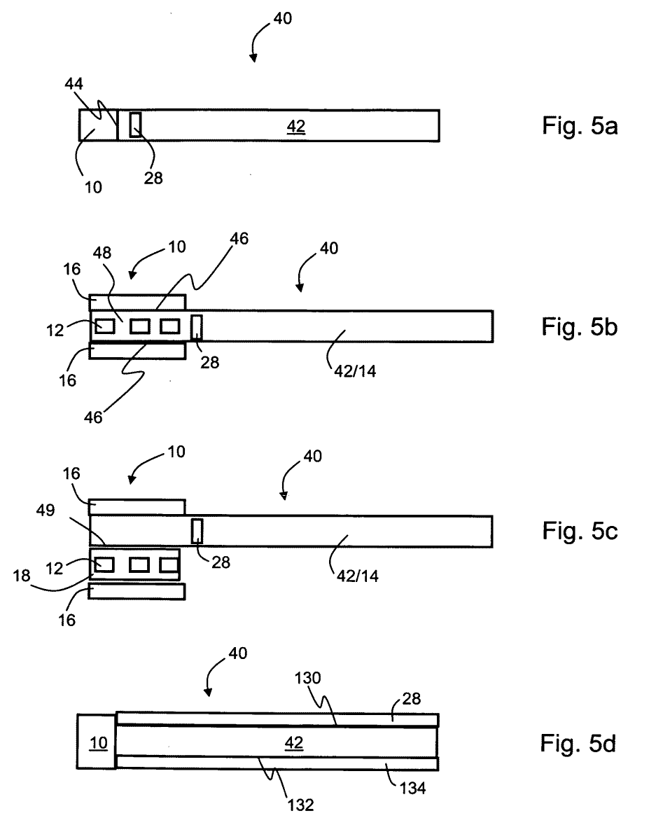

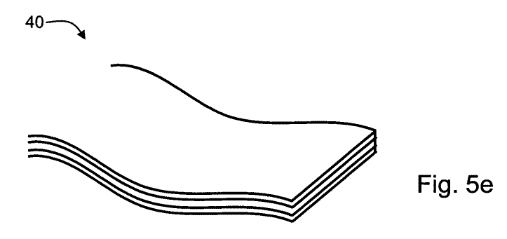

Reference is now made to FIGS. 5a-c which are schematic illustrations of illumination apparatus 40 according to various exemplary embodiments of the present invention. Apparatus 40 comprises a light distribution device 42 which is typically an optical waveguide (e.g., a surface emitting waveguide, an optical fiber, a waveguide sheet), and one or more light source devices which are preferably similar in their construction and operation to light source device 10. In various exemplary embodiments of the invention light distribution device is made, at least in part, of a waveguide material which is similar or identical to waveguide material 14.

The light source devices are optically coupled to the light distribution device such that the light source devices provide optical input to the light distribution device. The coupling between light source device 10 and light distribution device 42 can be done in more than one way.

In one embodiment, illustrated in FIG. 5a, device 10 is aligned with an end 44 of device 42. Being substantially circumferential, the illumination profile of device 10 complies with the optical aperture requirement of device 42 with menial optical losses.

In another embodiment, illustrated in FIG. 5b, light emitting elements 12 of device 10 are embedded in light distribution device 42 at a light generation region 48, such that device 42 serves also as waveguide material 14. In this embodiment, reflectors 16 are positioned at opposite surfaces 46 of device 42 such that light generation region 48 is sandwiched by reflectors 16. In operation, elements 12 emit light and reflectors 16 redirect it back to allow propagation of the light within device 42.

In an additional embodiment, illustrated in FIG. 5c, light emitting elements 12 of device 10 are embedded in optical funnel 18. In this embodiment, funnel 18 is attached to surface 46b of device 42 to form a contacting interface 49, and reflectors are positioned at the surfaces of funnel 18 and device 42 which are opposite to interface 49. In operation, light generated by elements 12 enters device 42 through interface 49. Light rays impinging on reflectors 16 are redirected into funnel 18 or device 42.

In any of the above embodiments, one or more photoluminescent layers 28 can be embedded in or disposed on one or more of the surfaces of light distribution device 42. Such configuration allows controlling on the profile of the light propagating within device 42 according to the principle described above. In the embodiments illustrated in FIGS. 5a-c, layers 28 are embedded within device 42.

FIG. 5d is a schematic illustration of apparatus 40 in an embodiment in which layer 28 is disposed on the surface of device 42. When device 42 distributes light only from one surface 130, the other surface 132 can be coated with or mounted on a reflector 134 which prevents emission of light through surface 132 and therefore enhances emission of light through the light emitting surface 130. reflector 134 can be made of any light reflecting material.

It is to be understood that although apparatus 40 appears to be flat in FIGS. 5a-d, this need not necessarily be the case since for some applications it may not be necessary for apparatus 40 to be flat. FIG. 5e schematically illustrates a perspective view of apparatus 10 in a preferred embodiment in which light distribution device 42 is non-planar.

Following is a description of a suitable waveguide material which can be used, according to various exemplary embodiments of the present invention for waveguide material 14, light distribution device 42 and/or funnel 18.

The waveguide material according to a preferred embodiment of the present invention comprises a polymeric material. The polymeric material may optionally comprise a rubbery or rubber-like material. The material can be formed by dip-molding in a dipping medium, for example, a hydrocarbon solvent in which a rubbery material is dissolved or dispersed. The polymeric material optionally and preferably has a predetermined level of cross-linking, which is preferably between particular limits. The cross-linking may optionally be physical cross-linking, chemical cross-linking, or a combination thereof. A non-limiting illustrative example of a chemically cross-linked polymer comprises cross-linked polyisoprene rubber. A non-limiting illustrative example of a physically cross-linked polymer comprises cross-linked comprises block co-polymers or segmented co-polymers, which may be cross-linked due to micro-phase separation for example. The material is optionally cross-linked through application of a radiation, such as, but not limited to, electron beam radiation and electromagnetic radiation.

Although not limited to rubber itself, the material optionally and preferably has the physical characteristics of rubber, such as parameters relating to tensile strength and elasticity, which are well known in the art. For example, the waveguide material can be characterized by a tensile set value which is below 5%. The tensile set value generally depends on the degree of cross-linking and is a measure of the ability of the flexible material, after having been stretched either by inflation or by an externally applied force, to return to its original dimensions upon deflation or removal of the applied force.

The tensile set value can be determined, for example, by placing two reference marks on a strip of the waveguide material and noting the distance between them along the strip, stretching the strip to a certain degree, for example, by increasing its elongation to 90% of its expected ultimate elongation, holding the stretch for a certain period of time, e.g., one minute, then releasing the strip and allowing it to return to its relaxed length, and re-measuring the distance between the two reference marks. The tensile set value is then determined by comparing the measurements before and after the stretch, subtracting one from the other, and dividing the difference by the measurement taken before the stretch. In a preferred embodiment, using a stretch of 90% of its expected ultimate elongation and a holding time of one minute, the preferred tensile set value is less than 5%. Also contemplated are materials having about 30% plastic elongation and less then 5% elastic elongation.

The propagation and diffusion of light through waveguide material can be done in any way known in the art, such as, but not limited to, total internal reflection, graded refractive index and band gap optics. Additionally, polarized light may be used, in which case the propagation of the light can be facilitated by virtue of the reflective coefficient of the material. For example, a portion of the material can be made of a dielectric material having a sufficient reflective coefficient, so as to trap the light within at least a predetermined region.

In any event, the material is preferably designed and constructed such that at least a portion of the light propagates therethrough at a plurality of directions, so as to allow the diffusion of the light in material. Additionally, the material is preferably designed and constructed to allow emission of light through the surface of the material. This embodiment is particularly useful for light distribution device 42 of apparatus 40, but it can also be employed for device 10.

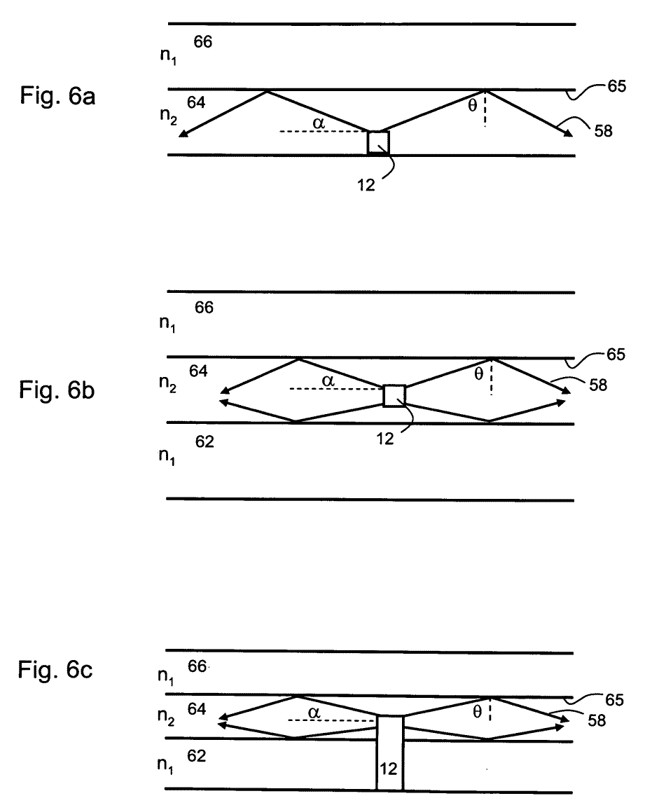

Reference is now made to FIGS. 6a-c, which illustrate an embodiment in which total internal reflection is employed. In this embodiment the waveguide material comprises a first layer 62 and a second layer 64. Preferably, the refractive index of layer 66, designated in FIGS. 6a-b by n₁, is smaller than the refractive index, n₂, of layer 64. In such configuration, when the light, shown generally at 58, impinges on internal surface 65 of layer 64 at an impinging angle, θ, which is larger than the critical angle, θ_{c}≡sin⁻¹(n₁/n₂), the light energy is trapped within layer 64, and the light propagates therethrough in a predetermined propagation angle, α. FIGS. 6b-c, schematically illustrate embodiments in which the waveguide material has three layers, 62, 64 and 66, where layer 64 is interposed between layer 62 and layer 66. In this embodiment, the refractive index of layers 62 and 64 is smaller than the refractive index of layer 64. As shown, light emitting element 12 can be embedded in layer 64 (see FIG. 6b) or it can be embedded in a manner such that it extends over two layers (e.g., layers 62 and 64 see FIG. 6c).

The light may also propagate through the material when the impinging angle is smaller than the critical angle, in which case one portion of the light is emitted and the other portion thereof continue to propagate. This is the case when the material comprises dielectric or metallic materials, where the reflective coefficient depends on the impinging angle, θ.

The propagation angle α is approximately ±(π/20), in radians. α depends on the ratio between the indices of refraction of the layers. Specifically, when n₂ is much larger than n₁, α is large, whereas when the ratio n₂/n₁ is close to, but above, unity, α is small. According to a preferred embodiment of the present invention the thickness of the layers of the material and the indices of refraction are selected such that the light propagates in a predetermined propagation angle. A typical thickness of each layer is from about 10 μm to about 3 mm, more preferably from about 50 μm to about 500 μm, most preferably from about 100 μm to about 200 μm. The overall thickness of the material depends on the height of light emitting element 12. For example, when light emitting element 12 is a LED device of size 0.6 mm (including the LED package), the height of the material is preferably from about 0.65 mm to about 0.8 mm. When light emitting element 12 is a bare die of size 0.1 mm, the height of the material is preferably from about 0.15 mm to about 0.2 mm.

The difference between the indices of refraction of the layers is preferably selected in accordance with the desired propagation angle of the light. According to a preferred embodiment of the present invention, the indices of refraction are selected such that propagation angle is from about 2 degrees to about 15 degrees. For example, layer 64 may be made of poly(cis-isoprene), having a refractive index of about 1.52, and layers 62 and 66 may be made of Poly(dimethyl siloxane) having a refractive index of about 1.45, so that Δn≡n₂−n₁≈0.07 and n₂/n₁≈0.953 corresponding to a propagation angle of about ±9 degrees.

According to a preferred embodiment of the present invention one or more of the layers of the material comprises at least one additional component designed and configured to redirect the propagated light, e.g., for enabling the emission of light through the surface of the material, improving light distribution therein and/or controlling the optical output. Following are several examples for the implementation of component 71, which are not intended to be limiting.

Referring to FIG. 7a, in one embodiment, component 71 is implemented as at least one impurity 70, present in second layer 64 and capable of emitting light, so as to change the propagation angle of the light. Impurity 70 may serve as a scatterer, which, as stated, can scatter radiation in more than one direction. When the light is scattered by impurity 70 in such a direction that the impinging angle, θ, which is below the aforementioned critical angle, θ_{c}, no total internal reflection occurs and the scattered light is emitted through surface 76. According to a preferred embodiment of the present invention the concentration and distribution of impurity 70 is selected such that the scattered light is emitted from a predetermined region of surface 76. More specifically, in regions of the material where larger portion of the propagated light is to be emitted through the surface, the concentration of impurity 70 is preferably large, while in regions where a small portion of the light is to be emitted the concentration of impurity 70 is preferably smaller.

As will be appreciated by one ordinarily skilled in the art, the energy trapped in the material decreases each time a light ray is emitted through surface 76. On the other hand, when the material is used as a light distribution device, it is often desired to use the material to provide a uniform surface illumination. Thus, as the overall amount of energy decreases with each emission, a uniform surface illumination can be achieved by gradually increasing the ratio between the emitted light and the propagated light. According to a preferred embodiment of the present invention, the increasing emitted/propagated ratio is achieved by an appropriate selection of the distribution of impurity 70 in layer 64. More specifically, the concentration of impurity 70 is preferably an increasing function of the optical distance which the propagated light travels.

Optionally, impurity 70 may comprise any object that scatters light and which is incorporated into the material, including but not limited to, beads, air bubbles, glass beads or other ceramic particles, rubber particles, silica particles and so forth, any of which may optionally comprise a photoluminescent material (phosphor and/or fluorophore as further detailed hereinabove) or biological material such as, but not limited to, Lipids. FIG. 7b illustrates an embodiment in which impurity 70 is implemented as a plurality of particles 77, distributed in an increasing concentration so is as to provide a light gradient. Particles 77 are preferably organized so as to cause light to be transmitted with substantially lowered losses through scattering of the light. Particles 77 may optionally be implemented as a plurality of bubbles in a solid plastic portion, such as a tube for example. According to a preferred embodiment of the present invention the size of particles 77 is selected so as to selectively scatter a predetermined range of wavelengths of the light. More specifically small particles scatter small wavelengths and large particles scatter both small and large wavelengths.

Particles 77 may also optionally act as filters, for example for filtering out particular wavelengths of light. Preferably, different types of particles 77 are used at different locations in the material. For example, particles 77 which are specific to scattering of a particular spectrum may preferably be used within the material at locations where such particular wavelength is to be emitted from the material to provide illumination.

According to a preferred embodiment of the present invention impurity 70 is capable of producing different optical responses to different wavelengths of the light. The difference optical responses can be realized as different emission angles, different emission wavelengths and the like. For example, different emission wavelengths may be achieved by implementing impurity 70 as beads each having predetermined combination of color-components, e.g., a predetermined combination of fluorophore molecules.

When a fluorophore molecule embedded in a bead absorbs light, electrons are boosted to a higher energy shell of an unstable excited state. During the lifetime of excited state (typically 1-10 nanoseconds) the fluorochrome molecule undergoes conformational changes and is also subject to a multitude of possible interactions with its molecular environment. The energy of excited state is partially dissipated, yielding a relaxed singlet excited state from which the excited electrons fall back to their stable ground state, emitting light of a specific wavelength. The emission spectrum is shifted towards a longer wavelength than its absorption spectrum. The difference in wavelength between the apex of the absorption and emission spectra of a fluorochrome (also referred to as the Stokes shift), is typically small.

Thus, in this embodiment, the wavelength (color) of the emitted light is controlled by the type(s) of fluorophore molecules embedded in the beads. Other objects having similar or other light emission properties may be also be used. Representative examples include, without limitation, fluorochromes, chromogenes, quantum dots, nanocrystals, nanoprisms, nanobarcodes, scattering metallic objects, resonance light scattering objects and solid prisms.

Referring to FIG. 7c, in another embodiment, component 71 is implemented as one or more diffractive optical elements 72 formed with layer 64, for at least partially diffracting the light. Thus, the propagated light reaches optical element 72 where a portion of the light energy is coupled out of the material, while the remnant energy is redirected through an angle, which causes it to continue its propagation through layer 64. Optical element 70 may be realized in many ways, including, without limitation, non-smooth surfaces of layer 64 and a mini-prism or grating formed on internal surface 65 and/or external surface 67 of layer 64. Diffraction Gratings are known to allow both redirection and transmission of light. The angle of redirection is determined by an appropriate choice of the period of the diffraction grating often called “the grating function.” Furthermore, the diffraction efficiency controls the energy fraction that is transmitted at each strike of light on the grating. Hence, the diffraction efficiency may be predetermined so as to achieve an output having predefined light intensities; in particular, the diffraction efficiency may vary locally for providing substantially uniform light intensities. Optical element 70 may also be selected such that the scattered light has a predetermined wavelength. For example, in the embodiment in which optical element 70 is a diffraction grating, the grating function may be selected to allow diffraction of a predetermined range of wavelengths.

Referring to FIG. 7d, in an additional embodiment, one or more regions 74 of layer 62 and/or 66 may have different indices of refraction so as to prevent the light from being reflected from internal surface 65 of second layer 64. For example, when n₃>n₂, where n₃ is the index of refraction of region 74, no total internal reflection can take place, because the critical angle, θ_{c}, is only defined when the ratio n₃/n₂ does not exceed the value of 1. The advantage of this embodiment is that the emission of the light through surface 76 is independent on the wavelength of the light.

As stated, the material from which funnel 18, device 42 and/or waveguide material 14 are made preferably comprises polymeric material. The polymeric material may optionally comprise natural rubber, a synthetic rubber or a combination thereof. Examples of synthetic rubbers, particularly those which are suitable for medical articles and devices, are taught in U.S. Pat. No. 6,329,444, hereby incorporated by reference as if fully set forth herein with regard to such illustrative, non-limiting examples. The synthetic rubber in this patent is prepared from cis-1,4-polyisoprene, although of course other synthetic rubbers could optionally be used. Natural rubber may optionally be obtained from Hevena brasiliensis or any other suitable species.

Other exemplary materials, which may optionally be used alone or in combination with each other, or with one or more of the above rubber materials, include but are not limited to, crosslinked polymers such as: polyolefins, including but not limited to, polyisoprene, polybutadiene, ethylene-propylene copolymers, chlorinated olefins such as polychloroprene (neoprene) block copolymers, including diblock-, triblock-, multiblock- or star-block-, such as: styrene-butadiene-styrene copolymers, or styrene-isoprene-styrene copolymers (preferably with styrene content from about 1% to about 37%), segmented copolymers such as polyurethanes, polyether-urethanes, segmented polyether copolymers, silicone polymers, including copolymers, and fluorinated polymers and copolymers.

For example, optionally and preferably, the second layer comprises polyisoprene, while the first layer optionally and preferably comprises silicone. If a third layer is present, it also optionally and preferably comprises silicone.

According to an optional embodiment of the present invention, the flexible material is formed by dip-molding in a dipping medium. Optionally, the dipping medium comprises a hydrocarbon solvent in which a rubbery material is dissolved or dispersed. Also optionally, the dipping medium may comprise one or more additives selected from the group consisting of cure accelerators, sensitizers, activators, emulsifying agents, cross-linking agents, plasticizers, antioxidants and reinforcing agents.

It is expected that during the life of this patent many relevant waveguide materials will be developed and the scope of the term waveguide materials is intended to include all such new technologies a priori.

Additional objects, advantages, and novel features of the present invention will become apparent to one ordinarily skilled in the art upon examination of the following examples, which are not intended to be limiting. Additionally, each of the various embodiments and aspects of the present invention as delineated hereinabove and as claimed in the claims section below finds experimental support in the following examples.

### EXAMPLES

Reference is now made to the following examples, which together with the above descriptions, illustrate the invention in a non limiting fashion.

### Example 1

### Computer Simulations

Computer simulations were performed to determine the properties of the light source device of the present embodiments. The computer simulations were for a light source device (confer FIG. 1a) having a top reflector and a bottom reflector, a light emitting element embedded in a funnel, and a waveguide material attached to the surface of the funnel.

The light emitting element was a light emitting diode obeying the Lambert's emission law, the reflectors were characterized by reflectivity of 98%, the light emitting elements characterized by a wavelength of 550 nm and intensity of 100 lm, the funnel and waveguide material were simulated as three layer structures. The indices of refraction for the layers were 1.570 and 1.502. The part of waveguide material which overlaps the funnel included impurities so as to enhance the scattering properties of the material.

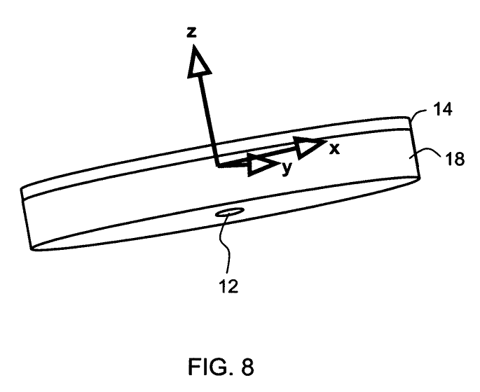

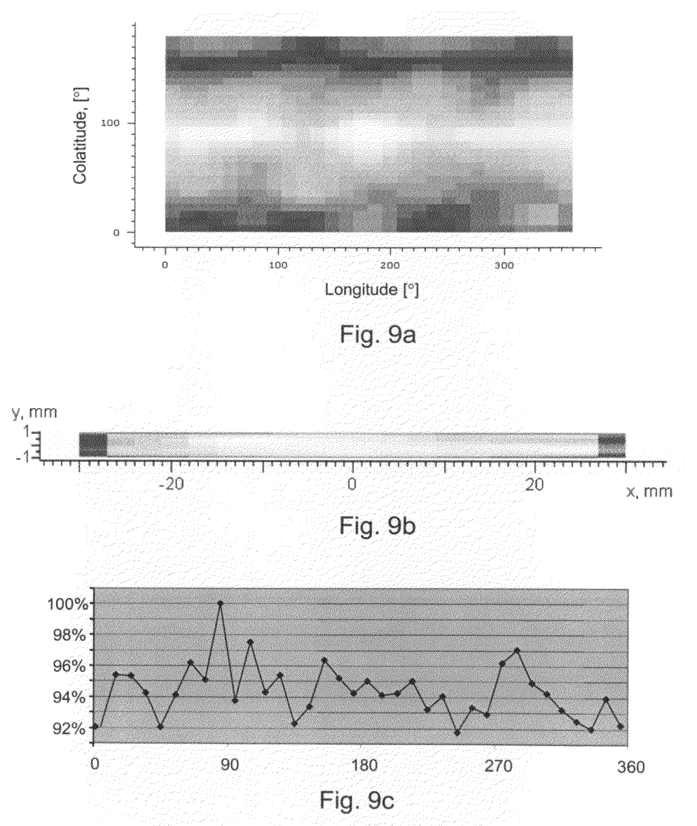

A fragmentary view of the simulation setup is illustrated in FIG. 8, showing the waveguide material 14, optical funnel 18 and light source 12. The simulation results are shown in FIGS. 9a-c.

FIG. 9a shows distribution of light emitted by the light source device as a function of the colatitude θ and longitude φ. For each pair of longitude-colatitude values, the intensity of the light is shown in FIG. 9a as a colored tile were tiles of brighter colors correspond to higher light intensities. As shown, the light intensity is a decreasing function of the variable |θ−90°|, with highest intensities along the line θ=90°. Thus, the light source device of the present embodiments has a substantially circumferential illumination profile.

FIG. 9b shows light distribution within the waveguide material. The coordinate system is selected such that the waveguide material is oriented parallel to the x-y plane (confer FIG. 1c). The intensity of light is represented by colors similarly to the representation in FIG. 9a. As shown, beside edge effects, the light distribution within the waveguide material is substantially uniform.

FIG. 9c shows the intensity of light emitted by the light source device as a function of φ, for θ=95°. The intensity of the emitted light is normalized to the highest value. As shown the intensity is substantially uniform with local deviations of less than 5%. The overall uniformity of the device can be quantified using I_{Max}, the maximal intensity and I_{MIN}, the minimal intensity, as: 1−(I_{Max}−I_{MIN})/(I_{Max}+I_{MIN}). By means of the results presented in FIG. 9c, the uniformity of the light is 0.96.

### Example 2

### Laboratory Experiments

An experimental light source device was manufactured according to the teachings of the present embodiments. The experimental device included (confer FIG. 1a) a top reflector and a bottom reflector, light emitting elements embedded in a funnel, and a waveguide material attached to the surface of the funnel.

The reflectors were made of 3M ESR foils and the light emitting elements were light emitting diodes of various wavelengths. For the funnel and waveguide material, several materials were tested: surface-emitting flexible waveguide material, edge-emitting flexible waveguide material, polymethyl methacrylate (PMMA) and transparent glass. The surface-emitting and edge-emitting waveguide materials were three layer structures made of Surlyn and Styrolux Polymers. The intermediate layer of the surface-emitting waveguide material included in addition impurities at a density of 10% to facilitate the emission of light through the surface of the waveguide.

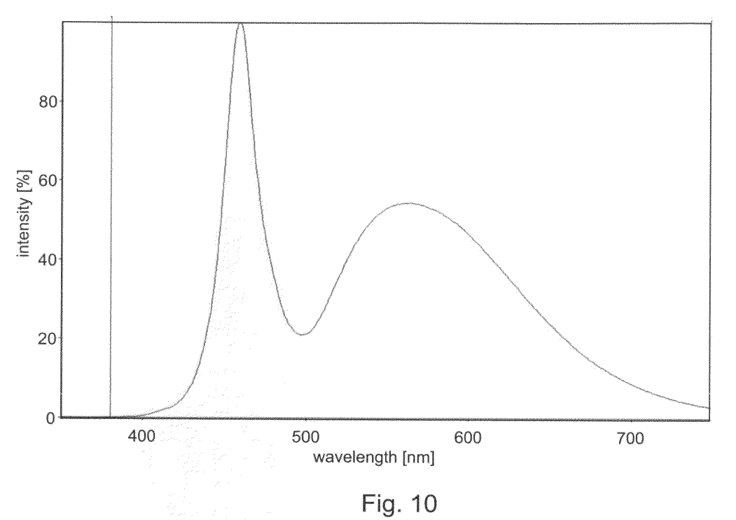

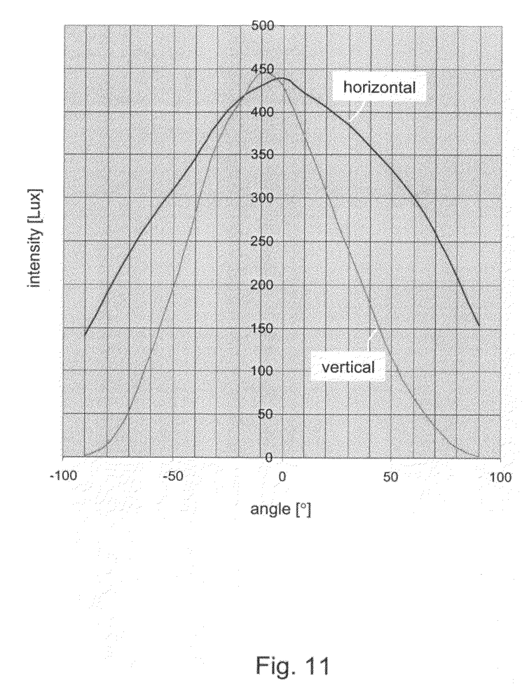

FIG. 10 shows the measured intensity as a function of the wavelength for the case of surface-emitting flexible waveguide material and a LED with a narrow direct emission spectrum centered at a wavelength of 460 nm, and a broad stokes shifted spectrum centered at about 560 nm. The overall light intensity in the integrated sphere is 34.3 lm. Similar measurements were made for the same LED separately from the experimental device, resulting in an overall intensity of 37.9 lm. Thus, the light source device of the present embodiments has a transmittance of 34.3/37.9=90%.

FIG. 11 shows results of an experiment in which the intensity of light emitted from the light source device of the present embodiments was measured for various vertical and horizontal angles. The measurement was by CAS140B Spectrometer (Instrument System, Munich, Germany). For each angle over a range of 180°, the intensity of the emitted light was measured and recorded. Horizontal angles in FIG. 11 correspond to latitudes (positive horizontal angles are measured anticlockwise from latitude 0, and negative horizontal angles are measured clockwise from latitude 0), and vertical angles FIG. 11 are latitudes. As shown, the dependence of the intensity on the latitude has a peak at latitude of 0° (colatitude of 90°) and is significantly narrower than the dependence on the longitude, demonstrating the ability of the device of the present embodiments to provide substantially circumferential illumination profile.

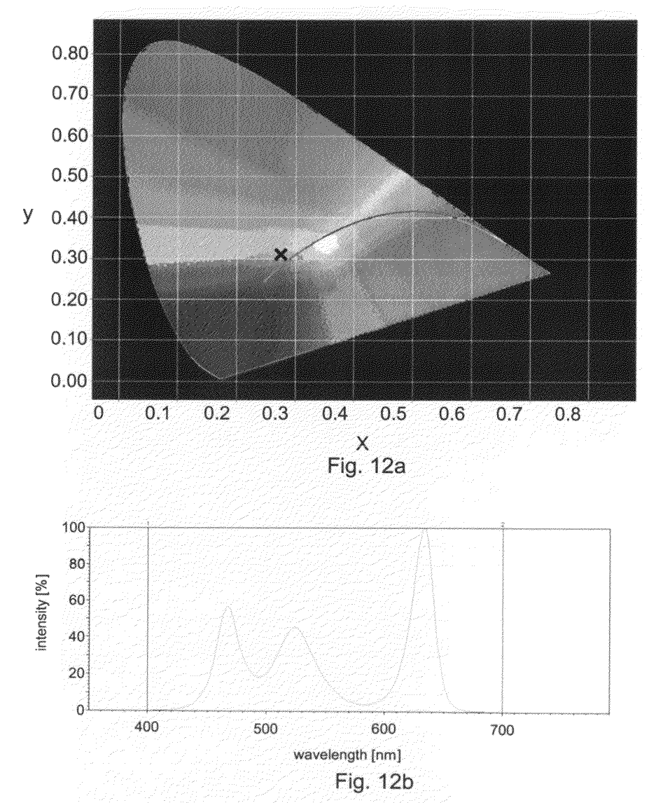

FIGS. 12a-b demonstrate the ability of the device of the present embodiments to allow color mixing. FIG. 12a shows a representation of the CIE 1931 color space, and FIG. 12b shows the obtained spectrum of the device for a color coordinate (X, Y, Z)=(0.3074, 0.3039, 0.3886) which is marked by a black cross on the color space of FIG. 12a. The conversion from the measured spectrum to the CIE color coordinate was performed according to the methods and formulae described in the RCA Electro-Optics Handbook (1974), page 50.

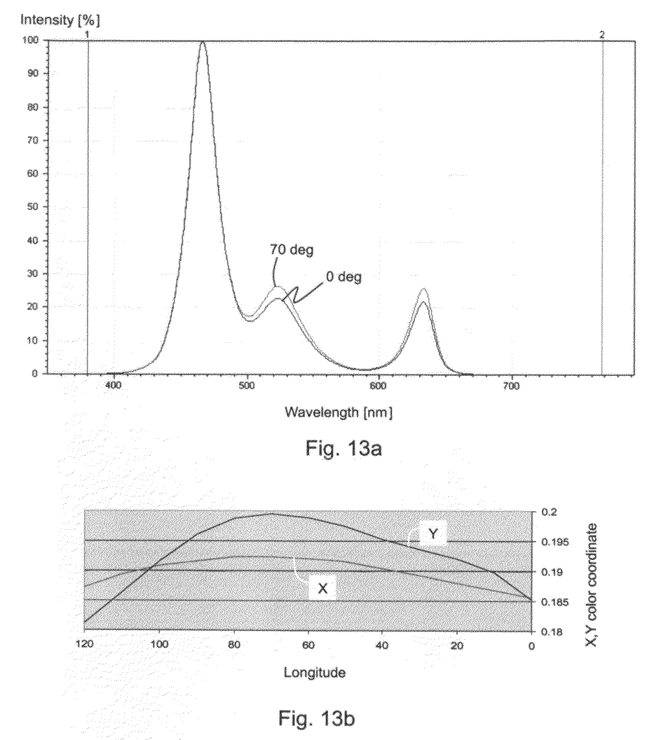

FIGS. 13a-b demonstrate the color mixing uniformity of the device of the present embodiments. FIG. 13a is the irradiance in W/m² nm, as a function of the wavelength at two extreme color coordinate positions, (X, Y, Z)=(0.1908, 0.1915, 0.6178) for horizontal position of 700, and (X, Y, Z)=(0.1858, 0.1824, 0.6318) for horizontal position of 0°. As shown, there is a significant overlap between the two irradiance curves. FIG. 13b shows the dependence of the observed X and Y color coordinates as a function of the longitude for an aperture of 120°. For both color coordinates, the variability over the entire aperture is less than ±0.01, demonstrating a highly uniform color output of the device.

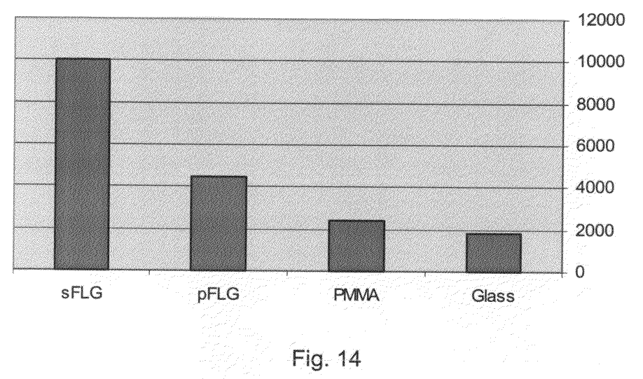

FIG. 14 shows a comparison between the optical outputs in the circumferential direction of the light source device of the present embodiments for different types of waveguide materials, 1 mm in thickness: surface-emitting flexible waveguide material (sFLG), edge-emitting flexible waveguide material (pFLG), PMMA and glass. The optical output was measured using a photometer positioned to collect circumferential light from the device. The same light source was used for all four materials and the light outputs are expressed in arbitrary units. As shown, the surface-emitting waveguide material has the highest optical output in the circumferential direction.

Table 1, lists results of experiments performed to determine the relative optical efficiency and mean free path of various materials. The experiments were performed on clear glass without impurities, PMMA without impurities and Lotek™ with impurities. The impurities were glass beads with volume density of 0.5% and Barium Sulfate (BaSO₄) particles with volume density of 1%, 0.5% and 0.25%.

The measurements were made by positioning the respective bulk material in front of a light emitting element and measuring the optical output through the bulk at the forward direction as a function of the thickness of the bulk. The value of the mean free path was defined as the thickness of the bulk material when the optical output of the light source at the forward direction is reduced by 50%. The value of the relative optical efficiency at mean free path t was defined as the ratio between the measured optical outputs with a bulk material of thickness t to the measured optical output without material.

Table 1 presents the measured mean free path, efficiency, normalized efficiency (normalization factor 0.657464), type of impurity, and the volume density of the impurity.

TABLE 1

| | mean | | normalized | | impurity |
|---|---|---|---|---|---|
| | free path | efficiency | efficiency | | volume |
| material | [mm] | [%] | [%] | impurity | density |
| Iotek ™ | 3 | 62% | 93.6% | BaSO₄ | 1% |
| Iotek ™ | 6 | 66% | 100.0% | BaSO₄ | 0.50% |
| Iotek ™ | 12 | 63% | 95.5% | BaSO₄ | 0.25% |
| Iotek ™ | 35 | 56% | 85.6% | Glass Beads | 0.50% |
| PMMA | 150 | 37% | 55.5% | — | Clear |
| Glass | 300 | 27% | 41.6% | — | Clear |

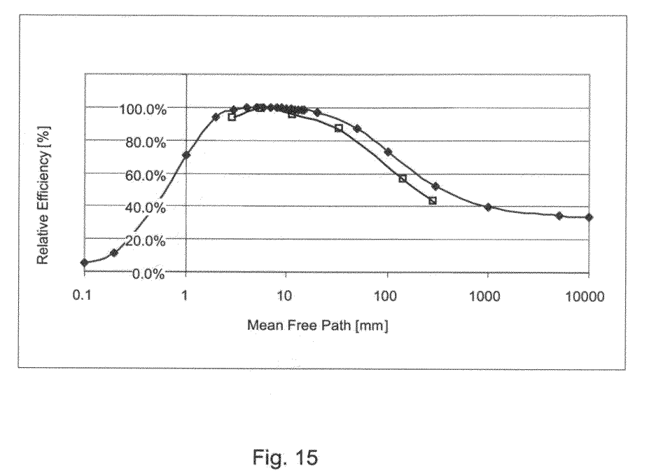

FIG. 15 shows the relative optical efficiency of the materials in Table 1 as a function of the mean free path (open squares). Also shown in FIG. 15 are computer simulations (filled squares) for various values of mean free paths ranging from 0.1 mm to 10,000 mm.

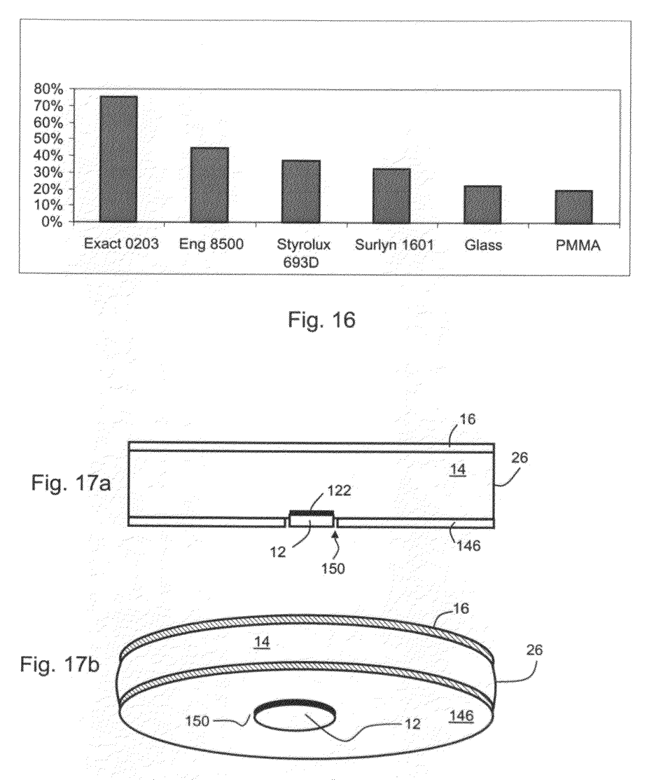

FIG. 16 is a histogram comparing the relative efficiency of the light source device of the present embodiments for various types of waveguides materials. The optical efficiency was defined as the ratio between the optical output in the circumferential direction and the total optical output. As demonstrated, materials having mean free path ranging from 1 mm to 100 mm (Styrolux 693D, Eng 8500 and Exact 0203, in the present Example) result in higher optical efficiency.

### Example 3

### Recycling Effect

Computer simulations were performed to determine the properties of the light source device of the present embodiments. In this example, the ability of the present embodiments to reduce the need of light recycling back onto the light emitting elements has been investigated.

The computer simulations were for a light source device as schematically illustrated in FIGS. 17a (cross sectional view) and 17b (perspective view). The device included circular waveguide material 14 and two reflectors 16 (front reflector) and 146 (rear reflector). Both reflectors 16 and 146 were simulated as specular reflectors. Light emitting element 12 was simulated as a LED having a square surface emitting area with a top electrode 122 thereon. The simulated position of the LED was in the center of waveguide material 14. Rear reflector 146 was simulated as having an opening 150 in the center for receiving the LED.

The simulations included solutions of the Maxwell equations for the propagation of light within the waveguide material. The integrated optical power at end 26 of the waveguide material was compared to the optical power generated by the LED to provide the efficiency of the device.

The waveguide material was simulated as being incorporated with particles. The particle diameter was about 5 μm. The waveguide substance was PMMA with refractive index of 1.5. The volume density of the particles was 0.5% (9000 particles per cubic millimeters).

Simulations were performed for two sizes of LEDs: one size was 1.5×1.5 mm² and another size was 0.5×0.5 mm². For each LED size both a fully transmissive (zero reflectivity) and a semi-transmissive (reflectivity of 50%) top electrode was simulated.

The radius of the reflectors (and waveguide) was 6 mm or 3 mm for both the 1.5×1.5 mm² LED, and the 0.5×0.5 mm² LED. Two types of particles ware simulated: BaSO₄ particles with a refractive index of 1.64, and SCHOTT Glass Ball particles with a refractive index of 1.9. The results are presented in Table 2 for the BaSO₄ particles and in Table 3 for the glass particles. In Tables 2 and 3, R represents the reflectivity of the top electrode.

TABLE 2

| | LED size: | | LED size: | |
|---|---|---|---|---|
| Reflector's type | 1.5 × 1.5 mm² | | 0.5 × 0.5 mm² | |
| and radius | R = 0 | R = 50% | R = 0 | R = 50% |
| specular, 6 mm | 60% | 64% | 62% | 62.7% |
| diffusive, 6 mm | 59% | 64.7% | 64.3% | 64.5% |
| specular, 3 mm | 59.7% | 65.4% | 63.5% | 64% % |
| diffusive, 6 mm | 59.7% | 65.4% | 67.9% | 68.2% |

TABLE 3

| | LED size: | | LED size: | |
|---|---|---|---|---|
| Reflector's type | 1.5 × 1.5 mm² | | 0.5 × 0.5 mm² | |
| and radius | R = 0 | R = 50% | R = 0 | R = 50% |
| specular, 6 mm | 57% | 64% | 63% | 64% |
| diffusive, 6 mm | 57% | 63.8% | 64% | 65.3% |
| specular, 3 mm | 61% | 66% | 69% | 70% |
| diffusive, 6 mm | 60% | 66.5% | 70.8% | 72% |

Tables 2 and 3 demonstrate that in the device of the present embodiments the reflectivity of top electrode 122 has only marginal effect on the optical efficiency.

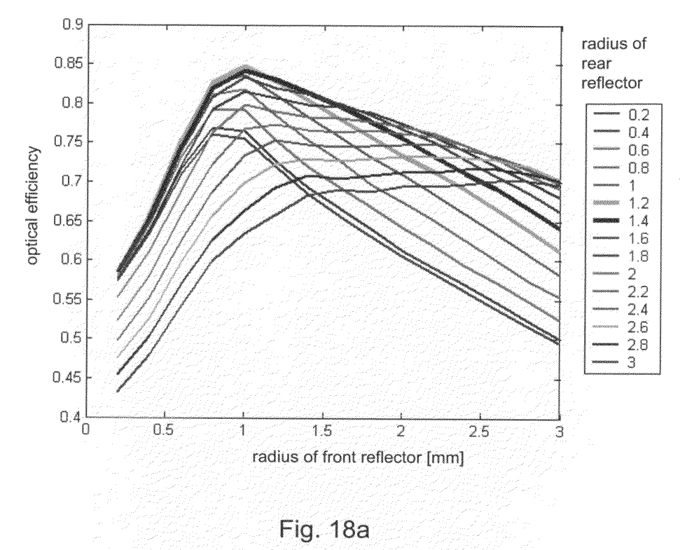

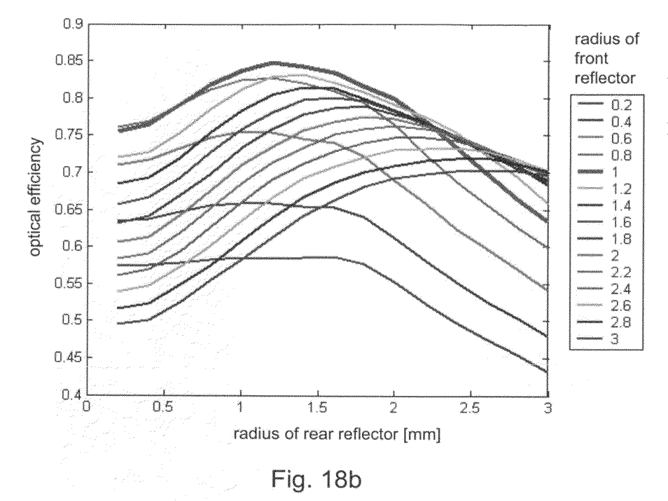

FIGS. 18a-b are graphs showing the optical efficiency as a function of the radii of the front reflector 16 and rear reflector 146, for the 0.5×0.5 mm² LED. The reflectivity of the reflectors in the results shown in FIGS. 18a-b was 98% for front reflector 16 and 90% for rear reflector 146.

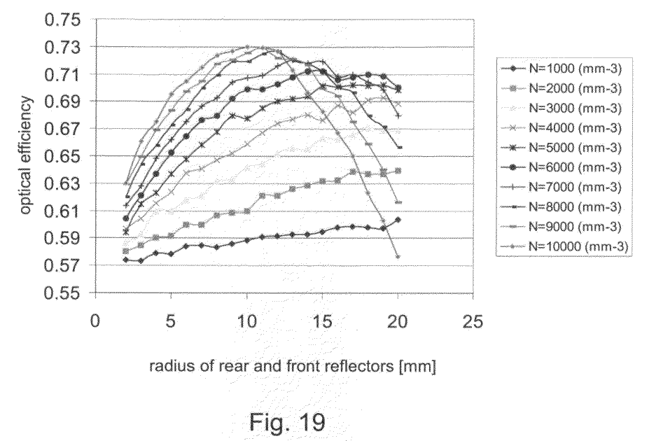

FIG. 19 are graphs showing the optical efficiency as a function of the radii of the front reflector 16 and rear reflector 146, for the 0.5×0.5 mm² LED, in embodiments in which the waveguide was incorporated with BaSO₄ particles. Shown are curves for different volume concentrations of particles. The volume concentrations are expressed in units number of particles per cubic millimeter. As shown, for concentration of 8,000-10,000 particles per cubic millimeter, the efficiency reaches a maximum of about 73% when the radius of both specular reflectors is about 12 mm. For concentration of 6,000-7,000 particles per cubic millimeter, the efficiency reaches a maximum of about 71% when the radius of both specular reflectors is about 14 mm. For lower concentrations the efficiency is monotonic as a function of the radii.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

What is claimed is:

1. A light source device, comprising:
at least one light emitting element;
an optical funnel being constituted for distributing light emitted by said at least one light emitting element into a waveguide material which is in optical communication with said optical funnel; and
at least one reflector contacting said waveguide material for redirecting light back into said waveguide material such as to reduce illumination exiting said waveguide material in any direction other than a circumferential direction.

2. A light source device, comprising:
at least one light emitting element;
a waveguide material for distributing light emitted by said at least one light emitting element; and
at least one reflector contacting said waveguide material for redirecting light back into said waveguide material such as to reduce illumination exiting said waveguide material in any direction other than a circumferential direction;
wherein a surface area of said reflector is at least two times the surface area of said at least one light emitting element and an optical efficiency of the light source device is at least 60%.

3. Illumination apparatus, comprising at least one light source device as claimed in claim 1, and a light distribution device being configured for distributing illumination provided by said at least one light source device.

4. Illumination apparatus, comprising at least one light source device as claimed in claim 2, and a light distribution device being configured for distributing illumination provided by said at least one light source device.

5. The apparatus of claim 3, wherein said light distribution device is an integral extension of said at least one light source device.

6. Illumination apparatus, comprising:
at least one light emitting element;
a waveguide material for distributing light emitted by said at least one light emitting element; and
at least one reflector contacting at least one surface of said waveguide material for redirecting light back into said waveguide material;
said waveguide material extending beyond said at least one reflector and being configured for distributing illumination through an extended portion of said at least one surface.

7. The device of claim 1, wherein at least one of said waveguide and said optical funnel is incorporated with particles capable of scattering said light.

8. The device of claim 1, wherein an illumination profile provided by the device is characterized in that at least 80% illumination is distributed within a colatitude range of from about 45° to about 135°.

9. The device of claim 1, wherein said optical funnel is an optical resonator being designed and constructed such that circumferential illumination provided by the device is substantially white.

10. The device of claim 1, wherein said optical funnel is an optical resonator being designed and constructed such that circumferential illumination provided by the device has a substantially uniform brightness.

11. The device of claim 1, wherein said optical funnel is adjacent to said waveguide material and being external thereto.

12. The device of claim 1, wherein said optical funnel is embedded in said waveguide material.

13. The device of claim 12, wherein said optical funnel protrudes out of a surface of said waveguide material.

14. The device of claim 12, wherein said optical funnel is flash with an external surface of said waveguide material said waveguide material.

15. The device of claim 1, wherein the device further comprising at least one optical element for deflecting said light upon entry to said optical funnel.

16. The device of claim 1, wherein said at least one reflector comprises a planar reflector.

17. The device of claim 1, wherein said at least one reflector comprises a non-planar reflector.

18. The device of claim 1, wherein said at least one reflector comprises a specular mirror.

19. The device of claim 1, wherein said at least one reflector comprises a Lambertian reflector.

20. The device of claim 1, wherein said at least one reflector comprises a diffusive reflector.

21. The device of claim 1, wherein said at least one reflector comprises a curved part and a generally planar part being peripheral to said curved part, said curved part being positioned opposite to a location of said at least one light emitting element.

22. The device of claim 1, wherein said at least one light emitting element is a light emitting diode.

23. The device of claim 22, wherein said light emitting diode is embedded within said waveguide.

24. The device of claim 22, wherein said light emitting diode is a bare die.

25. The device of claim 1, wherein said waveguide material comprises at least one photoluminescent layer.

26. The device of claim 25, wherein said at least one photoluminescent layer and said at least one light emitting element are selected such that a substantially white light exits said at least one photoluminescent layer.

27. The device of claim 1, wherein at least one of said waveguide and said optical funnel is incorporated with particles having photoluminescent properties.
